(19) United States
(12) Patent Application Publication
(10) Pub. No.: US 2011/0204376 A1
(43) Pub. Date: Aug. 25, 2011

(54) GROWTH OF MULTI-JUNCTION LED FILM STACKS WITH MULTI-CHAMBERED EPITAXY SYSTEM

(75) Inventors: Jie Su, Santa Clara, CA (US); David Bour, Cupertino, CA (US)

(73) Assignee: APPLIED MATERIALS, INC., Santa Clara, CA (US)

(21) Appl. No.: 12/871,617

(22) Filed: Aug. 30, 2010

Related U.S. Application Data
(60) Provisional application No. 61/307,192, filed on Feb. 23, 2010.

(51) Int. Cl. H01L 33/30; H01L 21/20

(52) U.S. Cl. 257/76; 438/46; 257/E21.09; 257/E33.023; 257/13

(57) ABSTRACT

Apparatus and method for growth of non-p-type GaN layers over p-type GaN layers. Embodiments include multi-junction LED film stacks, multi-junction LED devices paired into units and multi-junction LED arrays of the paired units. Epitaxial growths of p-type and non-p-type material layers are split between epitaxial chambers clustered onto a single platform to reduce p-type dopant cross-contamination. Arrayed multi-junction LED devices provide improved packing density and reduced blinking during AC operation.

### CLAIM OF PRIORITY

This application is related to, and claims priority to, the provisional utility application entitled “GROWTH OF MULTI-JUNCTION LED FILM STACKS WITH MULTI-CHAMBERED EPITAXY SYSTEM,” filed on Feb. 23, 2010, having an application No. 61/307,192 and attorney docket no. 014490L/ALRT/EES/NEON/ESONG.

### BACKGROUND

1. Field

Embodiments of the present invention pertain to the field of light-emitting diode (LED) fabrication and, in particular, to growth of multi-junction LED film stacks.

2. Description of Related Art

Group III-V materials are playing an ever increasing role in the semiconductor and related, e.g. light-emitting diode (LED), industries. Often, group III-V materials are difficult to grow or deposit in succession to form a film stack including a plurality of both n-type and p-type layers. Conventional III-V materials-based LED structures include only a single junction, which is typically grown in a single chamber without growth interruption. Due to the complex metal-organic precursors, the deposition process is accompanied with severe parasitic coatings, cross-contamination between different layers, and turn-on and turn-off delay for dopants, particularly magnesium (Mg).

### BRIEF DESCRIPTION OF THE DRAWINGS

Embodiments of the present invention is illustrated by way of example, and not by way of limitation, in the figures of the accompanying drawings, in which:

FIG. 1A is a flow diagram illustrating a method for epitaxial growth of a non-magnesium (Mg) doped film following growth of a Mg doped film, in accordance with an embodiment of the present invention;

FIG. 1B illustrates schematics of LED diode stacks including an n-type contact layer disposed over a p-type contact layer, in accordance with embodiments of the present invention;

FIG. 1C illustrates cross-sectional views of a GaN-based LED film stack, in accordance with an embodiment of the present invention;

FIG. 1D is a flow diagram illustrating a method for epitaxial growth of the GaN-based LED film stack depicted in FIG. 1C, in accordance with an embodiment of the present invention;

FIG. 1E illustrates cross-sectional views of a GaN-based LED film stack, in accordance with an embodiment of the present invention;

FIG. 1F is a flow diagram illustrating a method for epitaxial growth of the GaN-based LED film stack depicted in FIG. 1E, in accordance with an embodiment of the present invention;

FIGS. 1G and 1H illustrate cross-sectional views of GaN-based LED film stacks, in accordance with embodiments of the present invention;

FIGS. 1J and 1K illustrate cross-sectional views of GaN-based LED film stacks, in accordance with embodiments of the present invention;

FIGS. 1L and 1M illustrate cross-sectional views of GaN-based tunnel junctions which may be employed in the GaN-based LED film stacks depicted in FIGS. 1G, 1H, 1J, and 1K, in accordance with embodiments of the present invention;

FIGS. 1N and 1P illustrates cross-sectional views of GaN-based LED film stacks, in accordance with embodiments of the present invention;

FIG. 1Q illustrates a cross-sectional view of a GaN-based LED film stack, in accordance with an embodiment of the present invention;

FIGS. 1R and 1S illustrate cross-section views of GaN-based tunnel junctions which may be employed in the GaN-based LED film stacks depicted in FIGS. 1N, 1P, and 1Q, in accordance with embodiments of the present invention;

FIGS. 2A and 2B are schematic cross-sectional views of an MOCVD chamber, in accordance with an embodiment of the present invention;

FIG. 3 is a schematic view of an HVPE apparatus, in accordance with an embodiment of the present invention;

FIG. 4 is a schematic plan view of a multi-chambered epitaxy system, in accordance with an embodiment of the present invention;

FIG. 5 is a schematic of a computer system, in accordance with an embodiment of the present invention;

FIG. 6A illustrates a multi-LED unit employing a plurality of multi-junction devices formed in the GaN-based LED film stack depicted in FIG. 1C, in accordance with an embodiment of the present invention;

FIG. 6B illustrates a multi-LED unit employing a plurality of multi-junction devices formed in the GaN-based LED film stack depicted in FIG. 1E, in accordance with an embodiment of the present invention;

FIG. 6C illustrates a schematic of a plurality of the multi-LED units depicted in FIG. 6A or 6B coupled to an AC power source, in accordance with an embodiment of the present invention;

FIG. 6D illustrates a layout of the plurality of the first multi-LED units depicted in FIG. 6C, in accordance with an embodiment of the present invention;

FIGS. 7A and 7B illustrate multi-LED units employing a plurality of multi-junction devices formed in the GaN-based LED film stack depicted in FIG. 1C and FIG. 1E, respectively, in accordance with embodiments of the present invention;

FIG. 7C illustrates a schematic of a plurality of the multi-LED units depicted in FIG. 7A or 7B coupled to an AC power source, in accordance with an embodiment of the present invention;

FIGS. 8A and 8B illustrate multi-LED units employing a plurality of multi-junction devices formed in the GaN-based LED film stack depicted in FIG. 1C and FIG. 1E, respectively, in accordance with embodiments of the present invention;

FIGS. 9A and 9B illustrate multi-LED units employing a plurality of multi-junction devices formed in the GaN-based LED film stack depicted in FIG. 1G and FIG. 1L, respectively, in accordance with embodiments of the present invention;

FIG. 9C illustrates a schematic of a plurality of the multi-LED units depicted in FIG. 9A or 9B coupled to an AC power source, in accordance with an embodiment of the present invention;

FIG. 9D illustrates a cross-section of the second plurality of the multi-LED units depicted in FIG. 9C, in accordance with an embodiment of the present invention;

FIGS. 10A and 10B illustrate multi-LED units employing a plurality of multi-junction devices formed in the GaN-based LED film stack depicted in FIG. 1G and FIG. 1L, respectively, in accordance with embodiments of the present invention;

FIG. 10C illustrates a schematic of a plurality of the multi-LED units depicted in FIG. 10A or 10B coupled to an AC power source, in accordance with an embodiment of the present invention;

FIG. 10D illustrates a layout of the plurality of the multi-LED units depicted in FIG. 9C, in accordance with an embodiment of the present invention; and

FIG. 10E illustrates a cross-section of the plurality of the multi-LED units depicted in FIG. 10D, in accordance with an embodiment of the present invention.

### SUMMARY

Light-emitting diodes (LEDs) and related devices may be fabricated from layers of group III-V films. Exemplary embodiments of the present invention relate to the growth of multiple LED junctions in group III-nitride films, such as, but not limited to gallium nitride (GaN) films. Unlike GaN-based LED structures with a single junction, the formation of the more complex LED stack structures described herein include multiple junctions. Such LED structures pose additional technical challenges due to the complex metalorganic precursors employed in the film growths which can form severe parasitic coatings on surfaces of the epitaxy chamber or reactor. Such coatings cause cross-contamination between different layers and also cause a turn on/off delay (i.e., chamber memory effect) for film dopant species having low vapor pressures (e.g., magnesium (Mg)). Abrupt film interfaces are therefore difficult to form in multi-layer device structures which attempt to grow layers atop those doped with Mg. Absent sufficiently abrupt interfaces, LED performance suffers.

Disclosed herein are growth processes which separate different layer LED layer growths into different chambers to avoid cross contamination (mainly In and Mg, Mg and Si). In further embodiments, tunnel junctions are formed with a more abrupt Mg doping profile than possible for single chamber techniques. While numerous examples are provided herein of a modular chamber approach in which a transfer chamber module couples a plurality of chamber modules to form a cluster tool, it is to be appreciated that an in-line epitaxial system in which a substrate is conveyed from a first chamber portion to a second chamber portion between epitaxial depositions may also be utilized to practice embodiments of invention described herein.

In an embodiment, a Mg-free film layer is grown after a Mg-doped film layer is grown over a substrate with an abrupt Mg profile there between. In one such embodiment, a p-type layer film (e.g., pGaN) doped with Mg is grown in a first epitaxial chamber of a multi-chambered epitaxy system and a non-p-type-doped film (e.g., nGaN) substantially free of Mg is grown over the Mg-doped film layer in a second epitaxial chamber of the multi-chambered epitaxy system. For such methods, the non-Mg doped layer disposed over a Mg doped film layer forms an abrupt non-p-type material to p-type material junction. In particular embodiments, the Mg concentration transition between Mg-doped and non-Mg doped occurs over a material layer thickness no more than 10-50 nm. This is 2-6 times more abrupt than typical for a single chamber process which is at least 50-300 nm because of the chamber memory effect.

In further embodiments, a Si-free film layer is grown after a Si-doped film layer is grown over a substrate with an abrupt Si profile there between. In one such embodiment, a n-type layer film (e.g., nGaN) doped with Si is grown in a first epitaxial chamber of a multi-chambered epitaxy system and a p-type-doped film (e.g., Mg-doped GaN) substantially free of Si is grown over the Si-doped film layer in a second epitaxial chamber of the multi-chambered epitaxy system. For such methods, the non-Si doped layer disposed over a Si doped film layer forms an abrupt p-type material to non-p-type material junction.

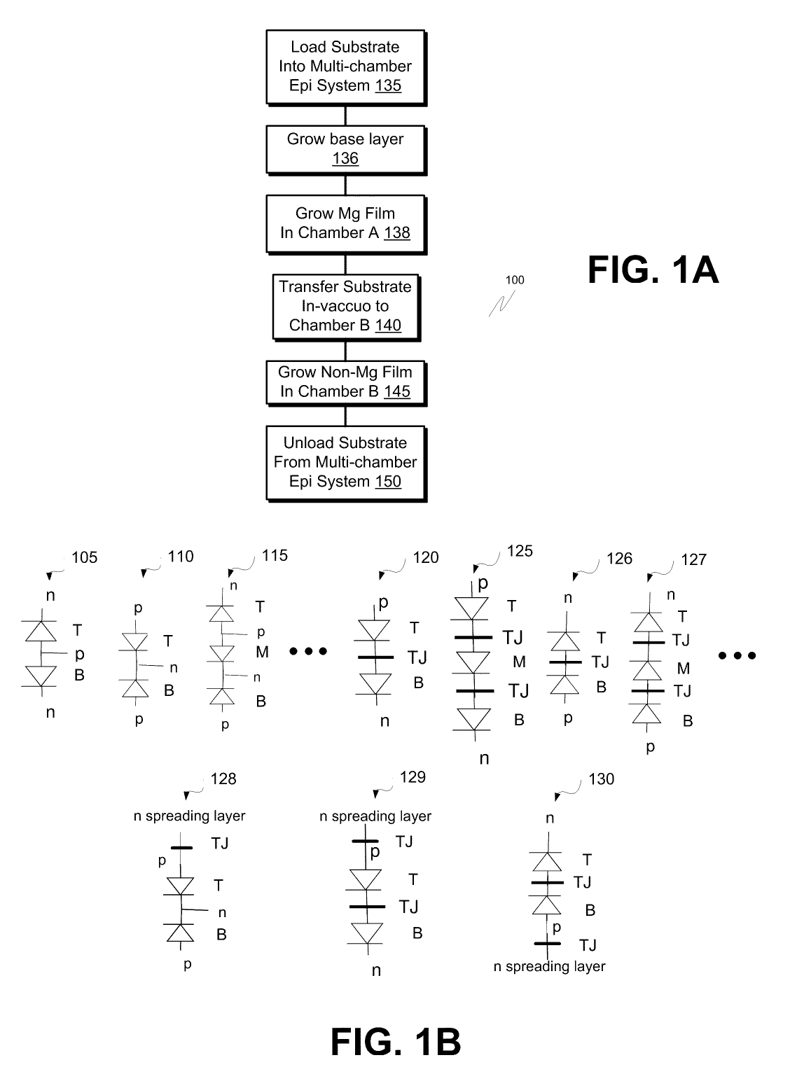

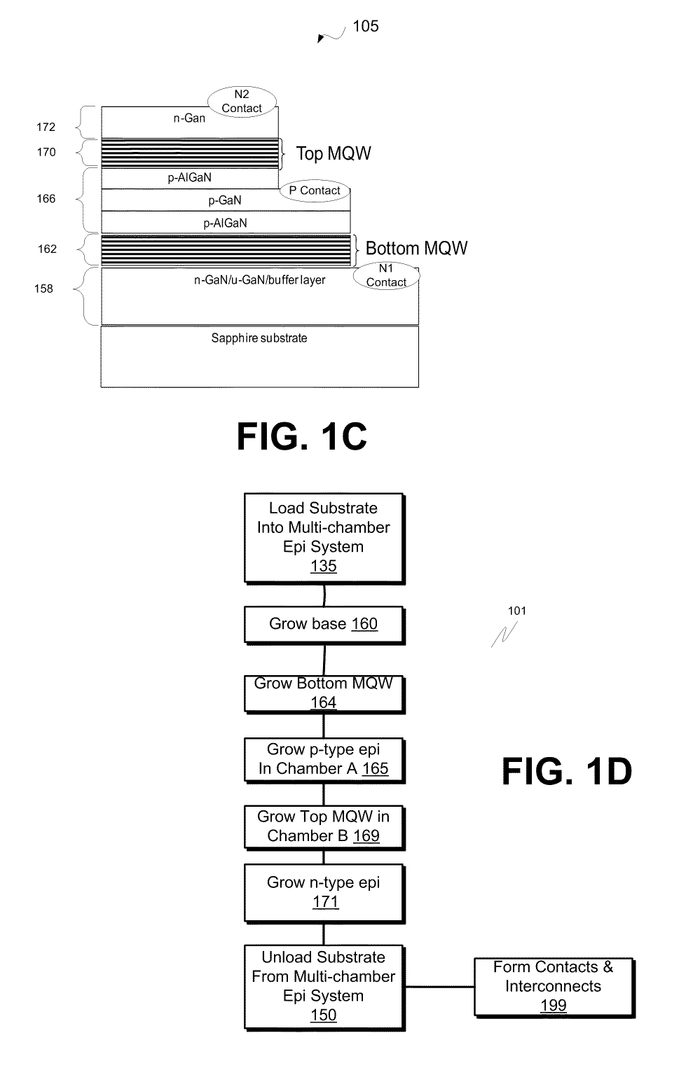

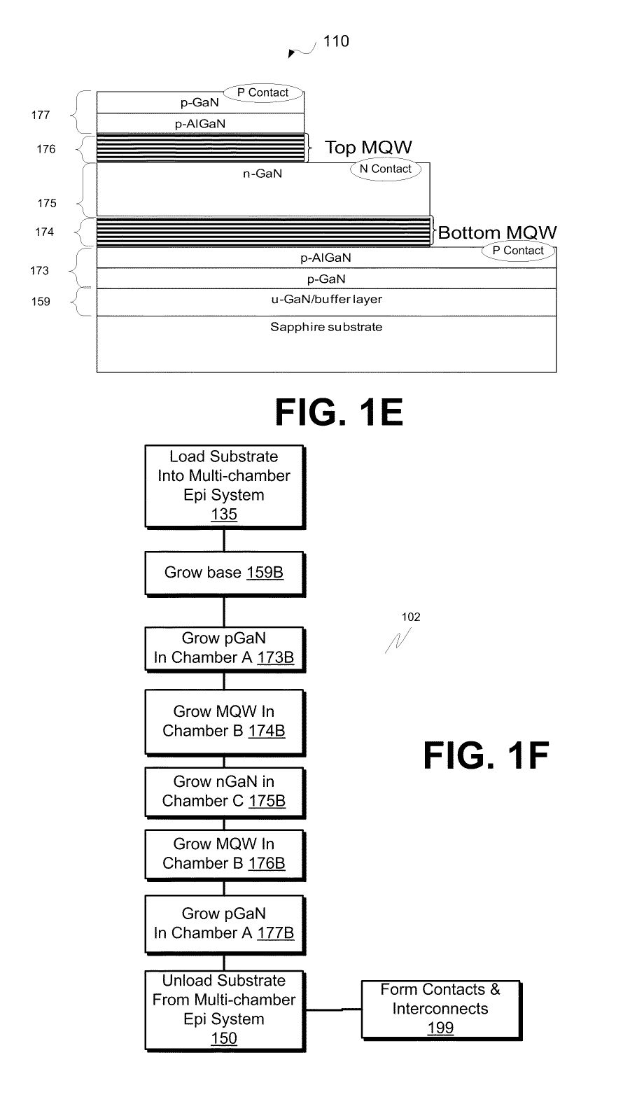

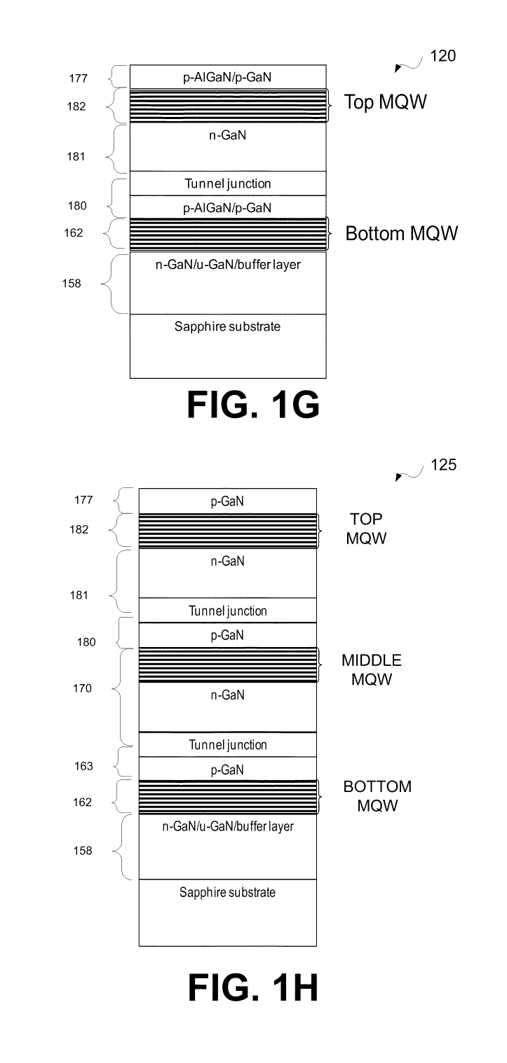

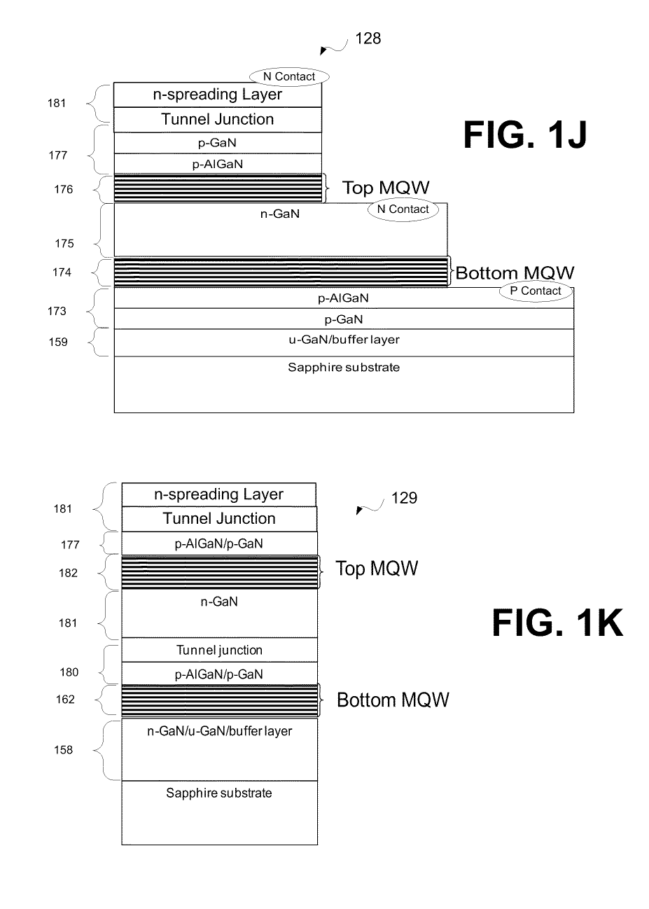

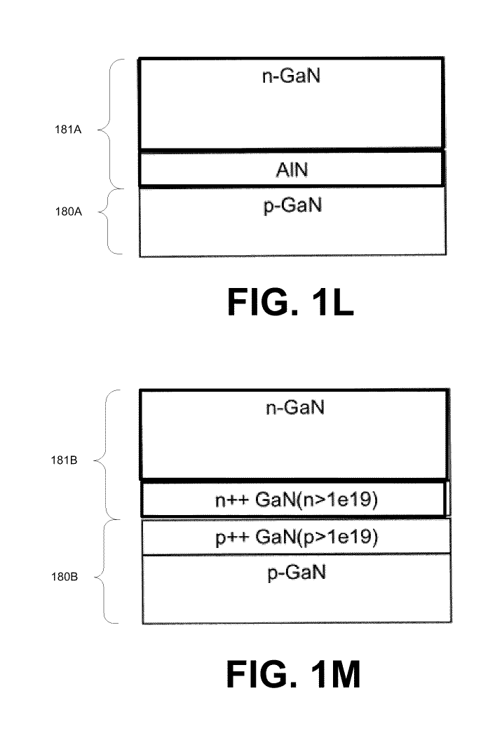

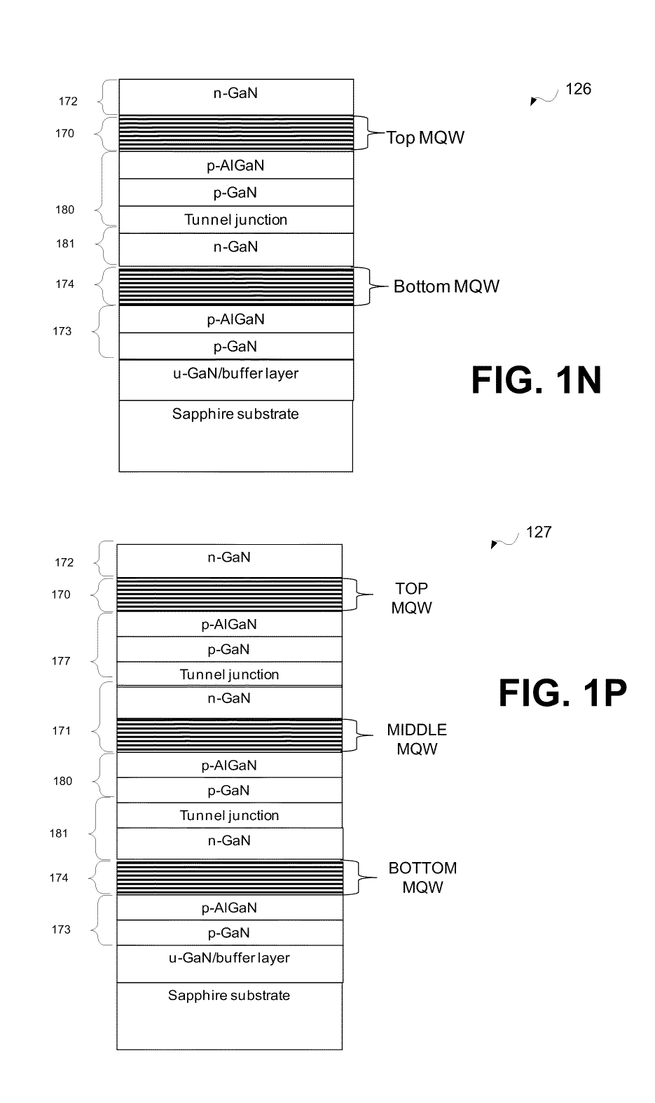

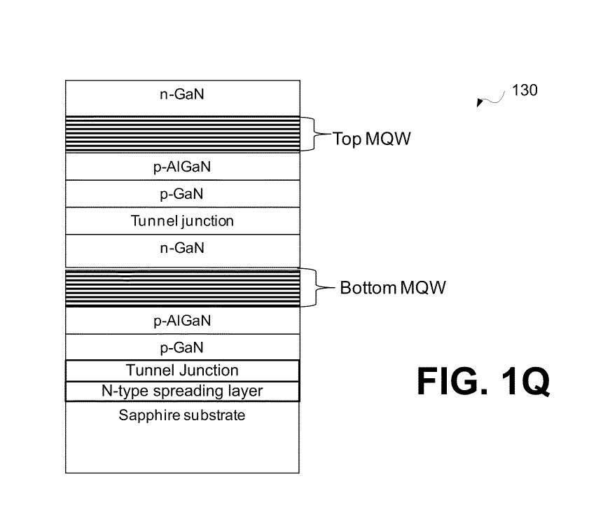

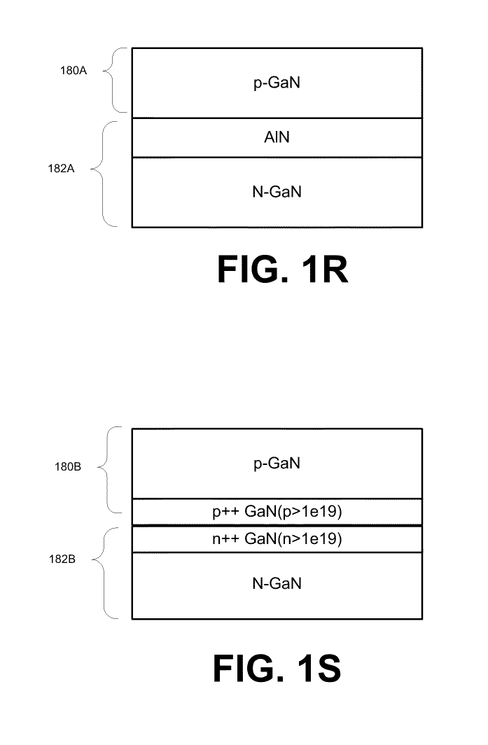

Also described herein are methods to form stacked diode structures in which the Mg-doped film layers are grown in a dedicated epitaxial chamber of a multi-chambered epitaxy system while the non-Mg doped film layers are grown in other epitaxial chambers of the multi-chambered epitaxy system. As shown in FIG. 1A, the growth method 100 begins with loading a substrate into a multi-chamber epitaxial system at operation 130. With the substrate loaded in a first chamber, a buffer layer may be grown at operation 125. On the buffer layer a first film layer is epitaxial grown using precursor gases known in the art for forming a Mg-doped film. The substrate is transferred in-vacuo (or at least in an oxygen-free environment), to a second epitaxy chamber at operation 140. At operation 145, the non-Mg film is grown in the second chamber. If, after the growth of the non-Mg-doped film there is to be a subsequent Mg-doped film growth, the substrate is returned to the first epitaxial chamber. Otherwise, the growth method 100 completes with unloading the substrate from the multi-chambered epitaxy system at operation 150. The growth method 100 may be repeated for any number of LED junctions to provide complex film stacks which have enhanced functionality due to the abruptness of the junctions possible with the Mg processing dedicated to less than all of the epitaxy chambers in the multi-chambered system.

Also described herein are multi-LED units comprising a plurality of stacked diode structures. In embodiments, pairs of multi-junction devices are provided as a unit based on the type of contact/interconnect metallization utilized to couple individual stacked diode structures together into the multi-LED units. Embodiments of arrays of the multi-LED units are also described for certain multi-LED pairings described herein. In further embodiments, the multi-LED units are to be coupled to an AC power source to provide AC LED arrays having advantages such as a reduced blinking effect, an increased monolithic packing density, a reduced device complexity, improved phosphor activation, and multi-wavelength emission.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

In certain embodiments, a stack of LED junctions having one or more common (i.e., shared) p-type or common n-type contacts is formed in a multiple-chamber cluster tool using the dedicated chamber approach illustrated in FIG. 1A. FIG. 1B illustrates schematics of exemplary embodiments of LED diode stacks which may be so formed. The advantages of such stacked LED junctions leverage the higher performance derived from abrupt achievable with a multiple-chamber split process to provide, for example, higher light output and increased device packing density compared with that of an LED having a single junction.

In one embodiment depicted in FIG. 1B, a common p-contact tandem LED stack 105 is formed. In another embodiment, a p-down tandem LED stack 110 including a common n-contact is formed. Both the p-down tandem LED stack 110 and common p-contact tandem LED stack 105 provide anti-series interconnection of a top diode (T) and a bottom diode (B). In a further embodiment, a three LED stack 115 includes both a common n-contact and common p-contact. In an embodiment, the common contact layers vertically tie the plurality of the LEDs into a parallel configuration.

In other embodiments, a tandem LED structures 120 or 126 with one coupling tunnel junction (TJ) provide pnpn series and p-down npnp series interconnection of the top diode T and bottom diode B. In other embodiments, p-down triple LED stacks 125, 127 including two tunnel junctions TJ provide pnpnpn series interconnection of the top diode T and bottom diode B with a middle diode (M).

In still other embodiments, the ability to form tunnel junctions with abrupt-interfaces is utilized to form tandem LED stacks 128, 129 and 130 having an n-type current spreading layer to improve current spreading and better hole injection. As shown in FIG. 1B, a tunnel junction TJ and an n-type current spreading layer is disposed upon the p-down tandem LED stack 110 to arrive at the tandem LED stack 128. Similarly, a tunnel junction TJ and an n-type current spreading layer is disposed upon the tandem LED structure 120 to arrive at the tandem LED stack 129 while a tunnel junction TJ and an n-type current spreading layer is disposed below the tandem LED stack 126 to arrive at the tandem LED stack 130. In other embodiments, indium tin oxide (ITO) is applied in place of the tunnel junction and n-type current spreading layer on top of a top p-GaN layer for better current spreading and reduce contact resistance. While the LED structures 105, 110, 115, 120, 125, 126, 127, 128, 129, and 130 exemplify the advantages provided through the multi-chamber process and the ability to form tunnel junctions with abrupt interface, one of skill in the art will appreciate these structures are not an exclusive list and other structures may also utilize such an approach.

FIG. 1C illustrates a cross-sectional view of a GaN-based LED film stack exemplifying the common p-contact tandem LED stack 105, in accordance with an embodiment of the present invention. FIG. 1D is a flow diagram illustrating a method for epitaxial growth of the LED film stack depicted in FIG. 1C. Generally, growth of each of the layers 162, 166, 170, and 172 may be performed in separate epitaxy chambers of a multi-chambered epitaxy system, with transfers between chambers performed in-vacuo (under vacuum). As described further elsewhere herein, each of the growths for layers 162, 166, 170, and 172 may be performed in a particular epitaxy chamber to prevent cross-contamination between indium (In) and Mg during layer growth. In addition to growth separation based on dopant species, for highest system throughput, commonly doped regions (e.g., 170 and 172) may also be grown either in the same epitaxy chamber or separate chambers.

As shown in FIG. 1C, the common p-contact tandem LED stack 105 is formed on a substrate. In one implementation, the substrate is single crystalline sapphire. Other embodiments contemplated include the use of substrates other than sapphire substrates, such as, germanium (Ge), silicon carbide (SiC), gallium arsenide (GaAs), zinc oxide (ZnO), lithium aluminum oxide (γ-LiAlO₂). Upon the substrate, are one or more base layers 158 which may include any number of group III-nitride based materials, such as, but not limited to, GaN, InGaN, AlGaN. The substrate and buffer layers may provide either a polar GaN starting material (i.e., the largest area surface is nominally an (h k l) plane wherein h=k=0, and l is non-zero), a non-polar GaN starting material (i.e., the largest area surface oriented at an angle ranging from about 80-100 degrees from the polar orientation described above towards an (h k l) plane wherein l=0, and at least one of h and k is non-zero), or a semi-polar GaN starting material (i.e., the largest area surface oriented at an angle ranging from about >0 to 80 degrees or 110-179 degrees from the polar orientation described above towards an (h k l) plane wherein l=0, and at least one of h and k is non-zero). One or more bottom n-type epitaxial layers are further included in the base layer 158 to facilitate a bottom contact. The bottom n-type epitaxial layers may be any doped or undoped n-type group III-nitride based materials, such as, but not limited to, GaN, InGaN, AlGaN.

As further depicted in FIG. 1C, a bottom multiple quantum well (MQW) structure 162 is disposed over the base layer 158. The bottom MQW structure 162 may be any known in the art to provide a particular emission wavelength. In a certain embodiments, the bottom MQW structure 162 may have a wide range of indium (In) content within GaN. For example, depending on the desired wavelength(s), the bottom MQW structure 162 may have between about a 10% to over 40% of mole fraction indium as a function of growth temperature, ratio of indium to gallium precursor, etc. It should also be appreciated that any of the MQW described herein may also take the form of single quantum wells (SQW) or double hetereostructures that are characterized by greater thicknesses than a QW.

Referring to FIG. 1D, the substrate is loaded into a first of a plurality of epitaxy chambers of a multi-chambered epitaxy system at operation 135 and a n-GaN/u-GaN/buffer layer stack is grown as a base layer 158 (FIG. 1C) at operation 160. The base layer 158 may be grown in an MOCVD or HVPE chamber, and in one embodiment is grown in a different chamber as those used for MQW and p-GaN (e.g., a three chamber process). The bottom MQW structure 162 (FIG. 1C) is then grown at operation 164. As further described elsewhere herein, the first epitaxy chamber may be a metalorganic chemical vapor deposition (MOCVD) chamber or a hydride/halide vapor phase epitaxy (HVPE) chamber, or another known in the art. Any growth techniques known in the art may be utilized with such chambers.

Referring back to FIG. 1C, one or more p-type epitaxial layers 166 are disposed over the bottom MQW structure 162. The p-type epitaxial layers 166 may include one or more layers of differing material composition. In the exemplary embodiment, the p-type epitaxial layers 166 include both p-type GaN and p-type AlGaN layers doped with Mg. In other embodiments only one of these, such as p-type GaN are utilized. As illustrated, where both p-type GaN and p-type AlGaN layers are present, a p-AlGaN layer forms the top surface of the p-type epitaxial layers 166 in preparation for a second active region including a top MQW structure. Other materials known in the art to be applicable to p-type contact layers for GaN systems may also be utilized. The thicknesses of the p-type epitaxial layers 166 may also vary within the limits known in the art.

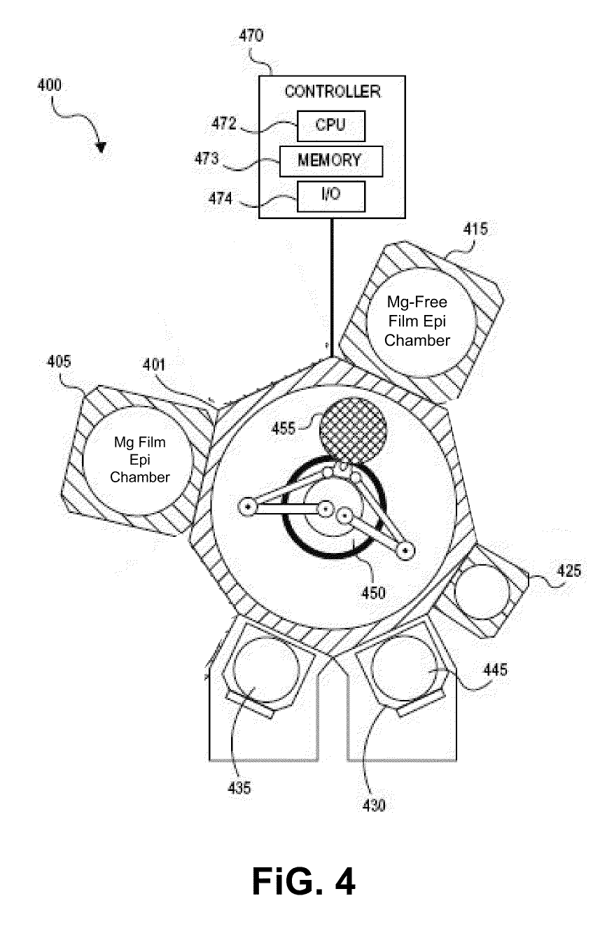

As shown in FIG. 1D at operation 165, the p-type epitaxial layers 166 are gown in an MOCVD or HVPE epitaxy chamber of the multi-chambered epitaxy system. Incorporation of Mg during the growth of the p-type epitaxial layers 166 may be by way of introduction of cp₂Mg to the epitaxy chamber, for example. In an embodiment, the p-type epitaxial layers 166 are grown using the same epitaxial chamber as was used for the bottom MQW structure 162. An abrupt junction between the bottom MQW structure 162 (non-p-type) and a bottom layer of the p-type epitaxial layers 166 is nonetheless possible where the bottom MQW structure 162 has not been previously exposed to species which induce an associated chamber memory effect. However in the exemplary embodiment, the substrate is first transferred in-vacuo from the first epitaxy chamber used for the bottom MQW structure 162 to a second epitaxy chamber of the multi-chambered epitaxy system dedicated to the growth of p-type epitaxial layers (e.g., Mg-doped film epitaxy chamber 405 of FIG. 4). The p-type dedicated epitaxy chamber is utilized to grow the one or more p-type epitaxial layers 166 so that the non-dedicated chambers (e.g., the Mg-free film epitaxy chamber 415) of the multi-chambered epitaxy system remain substantially free of the low vapor pressure Mg dopant species utilized in the p-type epitaxial layers. In an embodiment, because the substrate is transferred between epitaxy chambers in-vacuo, growth of the p-type epitaxial layers 166 over the bottom MQW structure 162 remains substantially monocrystalline and a substantially defect-free interface is formed between the top surface of the bottom MQW structure 162 and the bottom surface of the bottom p-type epitaxial layers 166. The crystallinity of the p-type epitaxial layers 166 epitaxially follows that of the top surface in the bottom MQW structure 162.

Returning to FIG. 1C, a top MQW structure 170 is disposed over the p-type epitaxial layers 166. The top MQW structure 170 may be substantially the same as the of the bottom MQW structure 162 (e.g., to provide higher emission efficiency for a given wavelength of light). Alternatively, the top MQW structure 170 may have a different composition and/or thickness than the bottom MQW structure 162 (e.g., to provide polychromatic emission). In embodiments, the top MQW structure 170 (non-p-type material) forms an abrupt metallurgical junction with the p-AlGaN layer of the p-type epitaxial layers 166. In embodiments, the width of the abrupt junction between the top MQW structure 170 and the p-AlGaN layer is approximately equal is no more than 20-50 nm. The abruptness of this junction improves the efficiency of the top MQW structure 170.

In the exemplary embodiment depicted in FIG. 1D, at operation 169 the top MQW structure 170 is epitaxially grown over the p-type epitaxial layers 166 in a different chamber than that utilized for the p-type GaN layer 166. The substrate therefore is first transferred in-vacuo from p-type epitaxial chamber (e.g., Mg film chamber 405 of FIG. 4) to an epitaxy chamber that is substantially free of Mg. For embodiments where the bottom MQW structure 162 and p-type epitaxial layers 166 are formed in a same epitaxy chamber, the top MQW structure 170 is grown in a second epitaxy chamber of the multi-chambered epitaxy system. For alternative embodiments where the bottom MQW structure 162 is grown in a first epitaxy chamber and the p-type epitaxial layers 166 are grown in a second (p-type dedicated) epitaxy chamber, the top MQW structure 170 may either be grown in the same chamber which grew the bottom MQW structure 162, or grown in a third epitaxy chamber of the multi-chambered epitaxy system. In either case, the top MQW structure 170 is grown in a chamber of multi-chambered epitaxy system which remains substantially free of Mg dopant species utilized in the growth of the p-type epitaxial layers 166. As such, the metallurgical junction between the bottom surface of the top MQW structure 170 and the top surface of the p-type epitaxial layers 166 forms an abrupt transition between a Mg doped film and a non-Mg doped film with the width of the abrupt junction being a function of solid state diffusion of Mg in the MQW material formed over the p-type epitaxial layers 166. In an embodiment, because the substrate is transferred from the p-type dedicated epitaxy chamber to the other epitaxy chamber in-vacuo, growth of the top MQW structure 170 remains substantially monocrystalline and a substantially defect-free interface is formed between the bottom surface of the top MQW structure 170 and the upper surface of the p-type epitaxial layers 166. The crystallinity of the top MQW structure 170 follows that of the top surface in the p-type epitaxial layers 166. In an embodiment, the surface is passivated by a sacrificial layer before transferring between epitaxy chambers. The sacrificial layer will protect the interface and will be easily decomposed before the deposition of the next device layer. A more detailed description of one such technique is provided in the U.S. provisional application entitled, “Surface Passivation Techniques for Multiple-Chamber Split Processes,” filed on Dec. 15, 2009, as application Ser. No. 61/286,696, herein incorporated by reference in its entirety for all purposes.

Returning to FIG. 1C, one or more top n-type GaN layers 172 are disposed over the top MQW structure 170 to complete the common p-contact tandem LED stack 105. The top n-type GaN layers 172 may be substantially the same as those formed as part of the starting material 158. Alternatively, the top n-type GaN layers 172 may have a different composition and/or thicknesses than the bottom n-type GaN layers.

In the exemplary embodiment depicted in FIG. 1D, at operation 171 the top n-type GaN layers 172 is epitaxially grown over the top MQW structure 170 either in the same epitaxy chamber in which the top MQW structure 170 was grown or in a different Mg-free chamber. The substrate therefore may be first transferred in-vacuo from a first Mg-free epitaxial chamber to a second Mg-free epitaxy chamber. For example, the top n-type GaN layers 172 may be grown in a same chamber which grew the bottom n-type GaN on the buffer (for embodiments where the starting material includes the buffer but lacks the bottom n-type GaN). For embodiments where the substrate is transferred between epitaxy chambers in-vacuo, the growth of the top n-type GaN layers 172 remains substantially monocrystalline and a substantially defect-free interface is formed between the bottom surface of the top n-type GaN layers 172 and the upper surface of the top MQW structure 170. The crystallinity of the top n-type GaN layers 172 follows that of the top MQW structure 170.

Following the growth of the common p-contact tandem LED stack 105, the substrate is unloaded from the multi-chambered epitaxy system at operation 150. Conventional patterning and etching techniques known in the art are performed to expose regions of the bottom n-type GaN layers (e.g., top surface of starting material 158), the top n-type GaN layers 172, and the p-type epitaxial layers 166. At operation 199, any contact metallization known in the art is applied to the exposed regions to form n-type electrode contacts (n1 and n2) and p-type electrode contact (p) for the common p-contact tandem LED stack 105. In exemplary embodiments, the n-type electrode is made of a metal stack, such as, but not limited to, Al/Au, Ti/Al/Ni/Au, Al/Pt/Au, or Ti/Al/Pt/Au. Exemplary p-type electrode embodiments include Ni/Au or Pd/Au. For either n-type or p-type contacts, a transparent conductor, such as Indium Tin Oxide (ITO), or others known in the art, may also be utilized. This same metallization or an a separate level of metallization may be used to interconnect the n-type and p-type contacts of the tandem LED stack 105 to form a multi-LED pair, as further described elsewhere herein.

FIG. 1E illustrates cross-sectional views of a p-down tandem LED stack 110, in accordance with an embodiment of the present invention. FIG. 1F is a flow diagram illustrating a method for epitaxial growth of the p-down tandem LED stack 110 depicted in FIG. 1E, in accordance with an embodiment of the present invention.

As illustrated in FIG. 1E, on the substrate (e.g., sapphire), one or more undoped GaN layers and buffer layer combine as a base layer 159. The base layer 159 (undoped GaN/buffer layer) is formed substantially as described in the context of the base layer 158. The base layer 159 may be grown at operation 159B (FIG. 1F) in an MOCVD or HVPE chamber, and in one embodiment is grown in a different chamber as those used for the MQW and p-GaN (e.g., a three chamber process). In the p-down tandem LED stack 110, one or more bottom p-type epitaxial layers 173 are disposed over the base layer 159. The bottom p-type epitaxial layers 173 may be any of those described for the p-type epitaxial layers 166. As illustrated in the exemplary method depicted in FIG. 1F, after the formation of the base layer 159 at operation 152, the bottom p-type epitaxial layers 173 are grown in a first epitaxy chamber of a multi-chambered epitaxy system at operation 174B. In an embodiment, the first epitaxial chamber is dedicated to the growth of Mg doped film layers.

Returning to FIG. 1E, a first active region having a bottom MQW structure 174, a second active region having a top MQW structure 176, and one or more intervening n-type GaN layers 175, is disposed over the bottom p-type epitaxial layers 173. The top and bottom MQW structures 174, 176 may comprise any of the combinations of materials described for the top and bottom MQW structures 162 and 170 to provide a multiple of the same MQW structure or different MQW structures for different emission wavelengths. The intervening n-type GaN layer 175 may be substantially as described for the top n-type GaN layer 172. In a particular embodiment, the bottom MQW structure 174 forms an abrupt junction with the p-AlGaN layer in the bottom p-type epitaxial layers 173. For certain embodiments, this abrupt junction has a junction width no greater than 20-50 nm.

As shown in FIG. 1F, after the growth of the bottom p-type epitaxial layers 173 at operation 173B and before the growth of the bottom MQW structure 174, an in-vacuo transfer of the substrate between epitaxy chambers is performed. With growth of the bottom MQW structure 174 initiated in the Mg-free chamber, Mg cross-contamination is avoided. As further illustrated in FIG. 1F, each the bottom and top MQW structures 174, 176, and the intervening n-type GaN layer 175 are grown in two separate Mg-free epitaxy chambers at operations 174B, 175B, and 176B, respectively, with in-vacuo chamber transfers occurring between each layer growth.

Returning to FIG. 1E, one or more top p-type epitaxial layers 177 are disposed over the top MQW structure 176. Any of the materials utilized in the bottom p-type epitaxial layers 173 may be utilized in the top p-type epitaxial layers 177. For example, both p-GaN and p-AlGaN is utilized in the top p-type epitaxial layers 177 with the p-AlGaN disposed on the top MQW structure. Alternatively, p-GaN alone is utilized. As depicted in FIG. 1F, at operation 177B the top p-type epitaxial layers 177 is grown in the same epitaxy chamber used to form the bottom p-type epitaxial layers 173. For such embodiments, the substrate is transferred from the epitaxy chamber in which the top MQW structure 176 was grown prior to the growth of the top p-type epitaxial layers 177 at operation 177B. In alternative embodiments, the top p-type epitaxial layers 177 are grown in the same epitaxy chamber in which the tandem active region stack 175 was grown. Because the materials present in certain embodiments of the top MQW structure 176, being free of Mg, do not induce a chamber history effect, an abrupt junction between the top p-type epitaxial layers 177 tandem active region stack 175 is possible. Nevertheless, because growth of the top p-type epitaxial layers 177 will contaminate the epitaxy chamber with Mg, to maintain separation between Mg and Mg-free epitaxy chambers within the multi-chambered epitaxy system, it is preferable to transfer the substrate to an epitaxy chamber dedicated to Mg film growths prior to forming the top p-type epitaxial layers 177. With the p-down tandem LED stack 110 complete, the substrate is unloaded from the multi-chambered epitaxy system. Patterning of the epitaxial stack and contact metallization may then proceed substantially as described for the common p-contact tandem LED stack 105.

Using the multi-chamber growth techniques described in the context of FIGS. 1C-1F, one may produce a wide variety of vertically stacked LEDs for tandem, triple, etc., devices which include abrupt junctions disposed over one or more Mg doped p-type GaN layers.

In other embodiments, multi-chambered growth techniques are utilized to form stacked LED structures including one or more tunnel junctions with the different LED junctions separated by a tunnel junction. With the connection of two or more LED junctions in a single structure, the internal quantum efficiency will be increased by two or times that of single junction LED. FIG. 1G, for example, depicts a tandem LED structure 120 with one coupling tunnel junction. As another example, FIG. 1H depicts a LED stack 125 including a plurality of tunnel junctions with top, middle and bottom MQW structures. FIGS. 1J and 1K illustrate cross-sectional views of GaN-based LED film stacks 126 and 127, respectively, in accordance with embodiments of the present invention. In each of these exemplary structures, the tunnel junctions may be as further depicted in FIGS. 1L and 1M. FIGS. 1N, 1P, and 1Q illustrate cross-section views of GaN-based LED film stacks 128, 129 and 130, respectively, in accordance with further embodiments of the present invention. In each of these exemplary structures, the tunnel junctions may be as further depicted in FIGS. 1R and 1S.

Referring to FIG. 1G, the bottom MQW structure 162, as described elsewhere herein, is disposed on the base layer 158, also described elsewhere herein. In one embodiment, the bottom MQW structure 162 is epitaxially grown in a first epitaxy chamber of a multi-chambered epitaxy system. Disposed over the bottom MQW structure 162 are one or more p-type epitaxial layers 180. In the exemplary embodiment depicted, p-type epitaxial layers 180 include a p-type GaN disposed on a p-type AlGaN layer. In a particular embodiment, one or more of the p-type epitaxial layers 180 is grown in a different epitaxy chamber of the multi-chambered epitaxy system than that used for growth of bottom MQW structure 162. In other embodiments, one epitaxy chamber grows both the bottom MQW structure 162 and one or more of the p-type epitaxial layers 180.

Disposed over the p-type epitaxial layers 180 is a tunnel junction, an n-type GaN layer 181 and a top MQW structure 182. In a particular embodiment, each of the MQW layers is formed as a single continuous growth operation within a single epitaxial chamber different than that which grows the p-type epitaxial layers 180. In an alternative embodiment, each of the p-type epitaxial layers 180, n-type GaN layer 181, and a top MQW structure 182 is grown in a separate chamber.

In the tunnel junction embodiment depicted in FIG. 1L, a p-type GaN layer 180A is grown in a first epitaxy chamber (e.g., as part of the p-type epitaxial layers 180), the substrate is then transferred to a second epitaxy chamber of the multi-chambered epitaxy system and the tunnel junction is completed with growth of the AlN layer/n-type GaN layer stack 181A (e.g., as part of the single growth stack 181). In alternative embodiments, other thin insulating layers known in the art may replace the AlN. In the tunnel junction embodiment depicted in FIG. 1M, a degenerately doped p-type GaN layer/moderately doped p-type GaN layer stack 180B is formed in a first epitaxy chamber (e.g., as part of the p-type epitaxial layers 180), the substrate is then transferred to a second epitaxy chamber of the multi-chambered epitaxy system and the tunnel junction is completed with growth of a degenerately doped n-type GaN/moderately doped n-type GaN layer stack 181B (e.g., as part of the single growth stack 181).

In any of the tunnel junction embodiments depicted in FIGS. 1L and 1M, a Mg p-type dopant may therefore be contained to the first epitaxy chamber and the tunnel junction formed more abruptly than would be possible if all layers of the tunnel junction are grown in a single epitaxy chamber. With the Mg p-type dopant absent during the growth of the non-p-type portion of the tunnel junction, the tunnel junction width may be reduced to no more than 10-50 nm. This is 2-6 times more abrupt than typical for a single chamber process which is at least 50-300 nm because of the chamber memory effect. As such, the tunneling efficiency may be significantly improved and the efficiency of the tandem LED structure 120 improved.

Returning to FIG. 1G, after formation of the tunnel junction, the n-type GaN layer 181 and top MQW structure 182 are formed substantially as described in the context of FIGS. 1C or 1E. One or more p-type epitaxial layers 177 are further disposed over the top MQW structure to complete the p-down tandem LED structure 120. In the particular embodiment depicted the p-type epitaxial layers 177 include a p-type AlGaN layer disposed on the top MWQ structure and a p-type GaN layer disposed on the p-type AlGaN layer. In one such embodiment, one or more of the p-type epitaxial layers 177 is grown in a separate epitaxy chamber than that used for the top MQW structure. For example, where the single growth stack 182 is grown in a Mg-free epitaxy chamber, the p-type epitaxial layers 177 are grown in an epitaxy chamber dedicated to Mg-doped film growths, such as the chamber utilized to grow the p-type epitaxial layers 180 and the p-doped layers of the tunnel junction.

With the formation of the p-type epitaxial layers 177, the tandem LED structure 120 is complete. Stack patterning and contact/interconnect metallization of a region on the n-type layer of the base layer 158 and a region of the p-type epitaxial layers 177 may then be performed by conventional means. In particular embodiments, a plurality of the tandem LED structures 120 are coupled by the contact metallization and/or interconnect metallization to form a first multi-LED pair which may be further arrayed together, as further described elsewhere herein.

FIG. 1H depicts a triple LED stack 125 including two tunnel junctions, the top and bottom tunnel junctions taking the form depicted in either FIGS. 1L or 1M. In one multi-chambered growth embodiment, each of the p-type doped layers 163, 180 and 177 are performed in a first epitaxial chamber while the non-p-type doped layers 162, 170, 181 and 182 are formed in a second epitaxial chamber to prevent cross contamination of Mg between the complementarily doped layers.

In further embodiments, multi-LED stacks include an n-type current spreading layer to improve current spreading and better hole injection. In the embodiment depicted in FIG. 1J, the tandem LED stack 128 is similar to the tandem LED structure 110 depicted in FIG. 1E with the addition of a tunnel junction and n-type doped spreading layer. The tunnel junction can again be any known in the art and in particular embodiments are as depicted in FIGS. 1L and 1M. Growths of the various layers in the tandem LED stack 128 may proceed substantially as described for the LED structure 110 with the p-type growth 177 further forming a p-type region of the tunnel junction. The workpiece is then transferred to a second epitaxial chamber to form region 181 including the n-type region of the tunnel junction and heavily doped n-type spreading layer. Likewise, for the embodiment depicted in FIG. 1K, the tandem LED stack 129 is similar to the tandem LED structure 120 depicted in FIG. 1G with the addition of a tunnel junction and n-type doped spreading layer. Growths of the various layers may proceed substantially as described for the LED structure 120 with the p-type growth 177 further forming a p-type region of the tunnel junction. The workpiece is then transferred to a second epitaxial chamber to form region 181 including the n-type region of the tunnel junction and heavily doped n-type spreading layer.

FIG. 1N illustrates one embodiment of the vertical LED stack 126 depicted in schematic form in FIG. 1B which employs a p-top tunnel junction 183 below a top MQW structure 170 and below an n-type GaN based layer 172. In one multi-chambered growth embodiment, each of the p-type doped layers 173 and 183 are performed in a first epitaxial chamber while the non-p-type doped layers 174, 175, 170 and 172 are formed in one or more separate, second epitaxial chamber(s) to prevent cross contamination of Mg between the complementarily doped layers, substantially as described elsewhere herein in the context of other vertical LED stack structure 105. The p-top tunnel junction 183 may be any known in the art and in particular embodiments is as further depicted in FIGS. 1R and 1S.

Referring to FIG. 1R, in one such embodiment, both the n-GaN and AlN portion 175A are formed in a first epitaxy chamber (e.g., as part of the growth of n-GaN 175 in FIG. 1N) while the p-type portion of the tunnel junction 183A is formed in a second, different, epitaxy chamber (e.g., as part of the growth of p-GaN 183 in FIG. 1N). In alternative embodiments, other thin insulating layers known in the art may replace the AlN. In the tunnel junction embodiment depicted in FIG. 1S, a degenerately doped n-type GaN layer/moderately doped n-type GaN layer stack 175B is formed in a first epitaxy chamber (e.g., as part of the n-type epitaxial layers 175 in FIG. 1N), the substrate is then transferred to a second epitaxy chamber of the multi-chambered epitaxy system and the tunnel junction is completed with growth of a degenerately doped p-type GaN/moderately doped p-type GaN layer stack 183B (e.g., as part of the single growth stack 183 in FIG. 1N).

FIG. 1P illustrates one embodiment of the vertical LED stack 127 depicted in schematic form in FIG. 1B which employs a plurality of p-top tunnel junctions below a top MQW structure and n-type GaN based electrode. In a particular multi-chambered growth embodiment, each of the p-type doped layers 173, 185 and 183 are performed in a first epitaxial chamber while the non-p-type doped layers 174, 184, 186, 175 and 172 are formed in one or more separate, second epitaxial chamber(s).

In the embodiment depicted in FIG. 1Q, the tandem LED stack 130 is similar to the tandem LED stack 126 depicted in FIG. 1N with the addition of a tunnel junction and n-type doped spreading layer disposed below all the MQW structures in the tandem LED device. The tunnel junctions can again be any known in the art and in particular embodiments are each as depicted in FIGS. 1R and 1S. Growths of the various layers in the tandem LED stack 130 may proceed substantially as described for the LED stack 126 with the additional heavily doped n-type current spreading layer 184 performed in a first epitaxy chamber, for example prefacing growth of n-type portion of the tunnel junction (e.g., as part of 175A or 178B in FIGS. 1R or 1S). The workpiece is then transferred to a second epitaxial chamber to form region 183 including the p-type region of the tunnel junction (e.g., 183B).

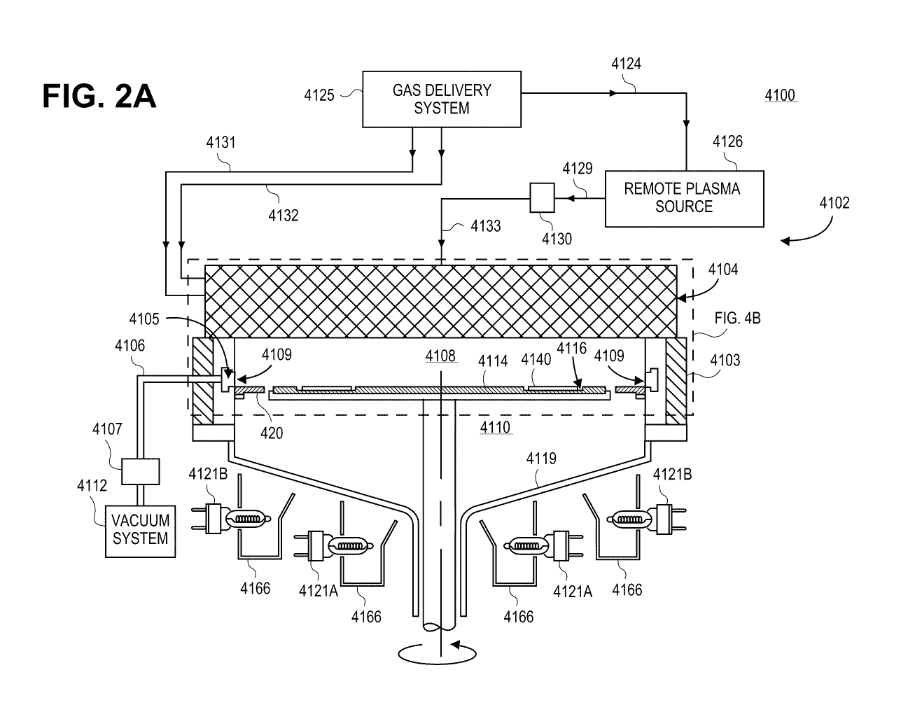

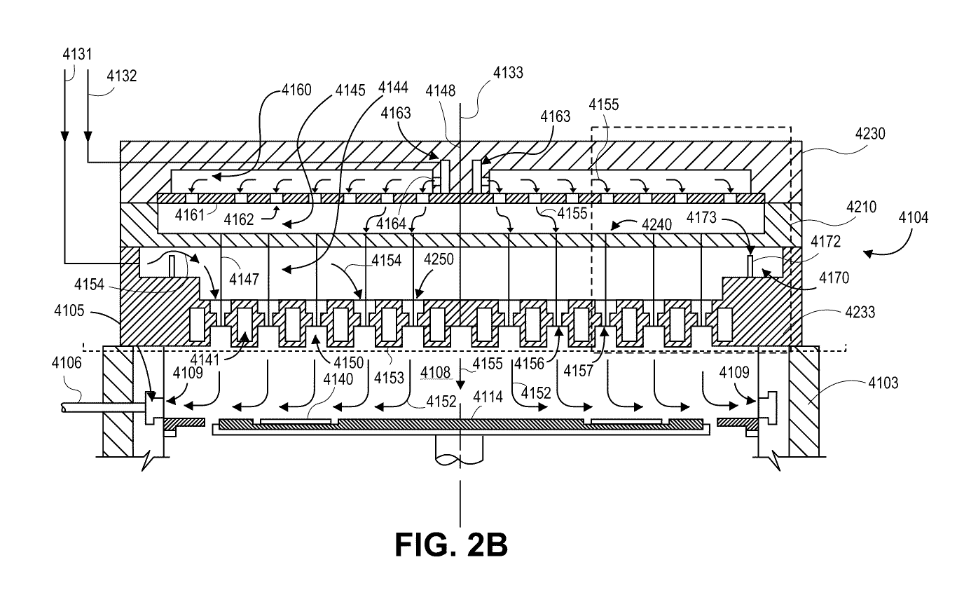

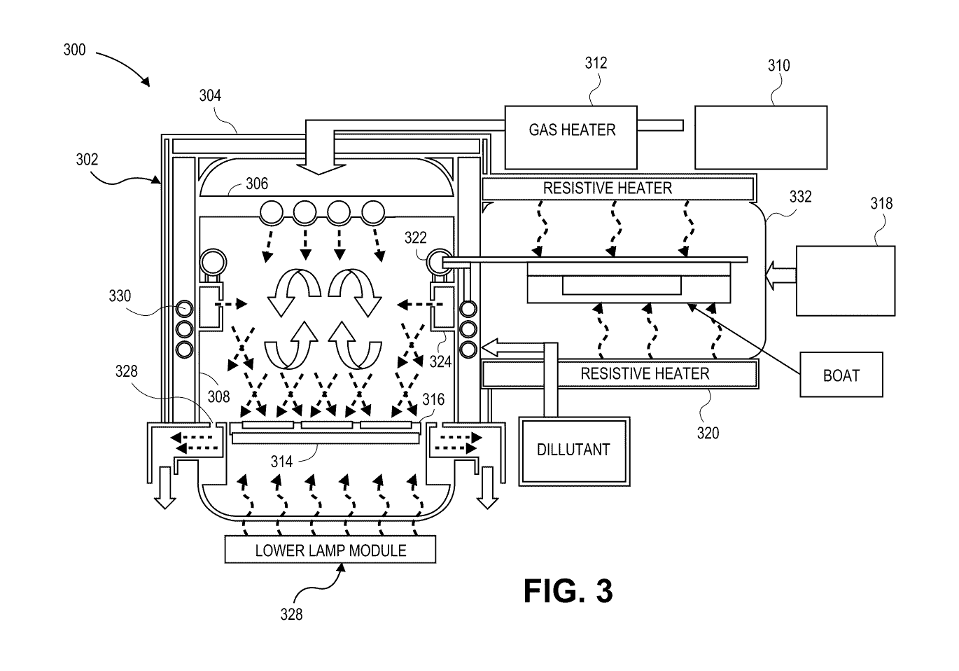

In embodiments, the various epitaxial layers described for the stacked LED structures may be grown by either of the epitaxy chambers depicted in FIGS. 2A, 2B and 3.

FIG. 2A is a schematic cross-sectional view of an MOCVD chamber which can be utilized in embodiments of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 4100 shown in FIG. 2A comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrates 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104, as described herein, may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

FIG. 4B is a detailed cross sectional view of the showerhead assembly shown in FIG. 4A, in accordance with an embodiment of the present invention. The showerhead assembly 4104 is located near the substrate carrier 4114 during substrate 4140 processing. In one embodiment, the distance from the showerhead face 4153 to the substrate carrier 4114 during processing may range from about 4 mm to about 41 mm. In one embodiment, the showerhead face 4153 may comprise multiple surfaces of the showerhead assembly 4104 which are approximately coplanar and face the substrates 4140 during processing.

During substrate 4140 processing, according to one embodiment of the invention, process gas 4152 flows from the showerhead assembly 4104 towards the substrate 4140 surface. The process gas 4152 may comprise one or more precursor gases as well as carrier gases and dopant gases which may be mixed with the precursor gases. The draw of the annular exhaust channel 4105 may affect gas flow so that the process gas 4152 flows substantially tangential to the substrates 4140 and may be uniformly distributed radially across the substrate 4140 deposition surfaces in a laminar flow. The processing volume 4108 may be maintained at a pressure of about 360 Torr down to about 80 Torr.

Reaction of process gas 4152 precursors at or near the substrate 4140 surface may deposit various metal nitride layers upon the substrate 4140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

In one embodiment, the showerhead assembly 4104 comprises an annular manifold 4170, a first plenum 4144, a second plenum 4145, a third plenum 4160, gas conduits 4147, blocker plate 4161, heat exchanging channel 4141, mixing channel 4150, and a central conduit 4148. The annular manifold 4170 encircles the first plenum 4144 which is separated from the second plenum 4145 by a mid-plate 2210 which has a plurality of mid-plate holes 2240. The second plenum 4145 is separated from the third plenum 4160 by blocker plate 4161 which has a plurality of blocker plate holes 4162 and the blocker plate 4161 is coupled to a top plate 2230. The mid-plate 2210 includes a plurality of gas conduits 4147 which are disposed in mid-plate holes 2240 and extend down through first plenum 4144 and into bottom plate holes 2250 located in a bottom plate 2233. The diameter of each bottom plate hole 2250 decreases to form a first gas injection hole 4156 which is generally concentric or coaxial to gas conduit 4147 which forms a second gas injection hole 4157. In another embodiment, the second gas injection hole 4157 may be offset from the first gas injection hole 4156 wherein the second gas injection hole 4157 is disposed within the boundary of the first gas injection hole 4156. The bottom plate 2233 also includes heat exchanging channels 4141 and mixing channels 4150 which comprise straight channels which are parallel to each other and extend across showerhead assembly 4104.

The showerhead assembly 4104 receives gases via supply lines 4131, 4132, and 4133. In another embodiment, each supply line 4131, 4132 may comprise a plurality of lines which are coupled to and in fluid communication with the showerhead assembly 4104. A first precursor gas 4154 and a second precursor gas 4155 flow through supply lines 4131 and 4132 into annular manifold 4170 and top manifold 4163. A non-reactive gas 4151, which may be an inert gas such as hydrogen (H₂), nitrogen (N₂), helium (He), argon (Ar) or other gases and combinations thereof, may flow through supply line 4133 coupled to a central conduit 4148 which is located at or near the center of the showerhead assembly 4104. The central conduit 4148 may function as a central inert gas diffuser which flows a non-reactive gas 4151 into a central region of the processing volume 4108 to help prevent gas recirculation in the central region. In another embodiment, the central conduit 4148 may carry a precursor gas.

FIG. 3 is a schematic view of an HVPE apparatus 300 which may be utilized, in accordance with embodiments of the present invention. The apparatus includes a chamber 302 enclosed by a lid 304. Processing gas from a first gas source 310 is delivered to the chamber 302 through a gas distribution showerhead 306. In one embodiment, the gas source 310 may comprise a nitrogen containing compound. In another embodiment, the gas source 310 may comprise ammonia. In one embodiment, an inert gas such as helium or diatomic nitrogen may be introduced as well either through the gas distribution showerhead 306 or through the walls 308 of the chamber 302. An energy source 312 may be disposed between the gas source 310 and the gas distribution showerhead 306. In one embodiment, the energy source 312 may comprise a heater. The energy source 312 may break up the gas from the gas source 310, such as ammonia, so that the nitrogen from the nitrogen containing gas is more reactive.

To react with the gas from the first source 310, precursor material may be delivered from one or more second sources 318. The precursor may be delivered to the chamber 302 by flowing a reactive gas over and/or through the precursor in the precursor source 318. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 332 and be heated with the resistive heater 320. By increasing the residence time that the chlorine containing gas is snaked through the chamber 332, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 320 within the second chamber 332 in a boat. The chloride reaction product may then be delivered to the chamber 302. The reactive chloride product first enters a tube 322 where it evenly distributes within the tube 322. The tube 322 is connected to another tube 324. The chloride reaction product enters the second tube 324 after it has been evenly distributed within the first tube 322. The chloride reaction product then enters into the chamber 302 where it mixes with the nitrogen containing gas to form a nitride layer on the substrate 316 that is disposed on a susceptor 314. In one embodiment, the susceptor 314 may comprise silicon carbide. The nitride layer may comprise gallium nitride for example. The other reaction products, such as nitrogen and chlorine, are exhausted through an exhaust 326.

As shown in FIG. 4, two or more epitaxy chambers, such as the MOCVD and HVPE chambers depicted in FIGS. 2 and 3, respectively, are coupled to a platform to form a multi-chambered epitaxy system. Embodiments described herein which utilize a intra-LED transfer of the substrate between two epitaxy chambers may be performed using the multi-chambered system depicted in FIG. 4. Referring to FIG. 4, the multi-chambered processing platform 400, may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

Embodiments of the present invention further include an integrated metrology (IM) chamber 425 as a component of the multi-chambered processing platform 400. The IM chamber 425 may provide control signals to allow adaptive control of integrated deposition process, such as the multiple segmented epitaxial growth processes described herein (e.g., growth method 100). Integrated metrology may be utilized as the substrate is transferred between epitaxy chambers. The IM chamber 425 may include any metrology described elsewhere herein to measure various film properties, such as thickness, roughness, composition, and may further be capable of characterizing grating parameters such as critical dimensions (CD), sidewall angle (SWA), feature height (HT) under vacuum in an automated manner. Examples include, but are not limited to, optical techniques like reflectometry and scatterometry. In particularly advantageous embodiments, in-vacuo optical CD (OCD) techniques are employed where the attributes of a grating formed in a starting material are monitored as the epitaxial growth proceeds.

The epitaxy chambers 405 and 415 perform particular growth operations on a substrate 455, as described elsewhere herein. In the exemplary embodiment, the plurality of epitaxial chambers 405 and 415 are separately dedicated to growth of Mg-doped films (405) and growth of Mg-free films (415). As further depicted in FIG. 4, the multi-chambered processing platform 400 further includes an optional substrate aligner chamber 425, as well as load lock chambers 430 holding cassettes 435 and 445, coupled to the transfer chamber 401 including a robotic handler 450.

In one embodiment of the present invention, control of the multi-chambered processing platform 400, including the robotic handler 450, is provided by a controller 470. The controller 470 may be one of any form of general-purpose data processing system that can be used in an industrial setting for controlling the various subprocessors and subcontrollers. Generally, the controller 470 includes a central processing unit (CPU) 472 in communication with a memory 473 and an input/output (I/O) circuitry 474, among other common components. Software commands executed by the CPU 472, cause the multi-chambered processing platform 400 to, for example, load a substrate into the first epitaxial chamber 405, execute a first growth process, transfer the substrate to the second epitaxial chamber 415 and execute a second growth process.

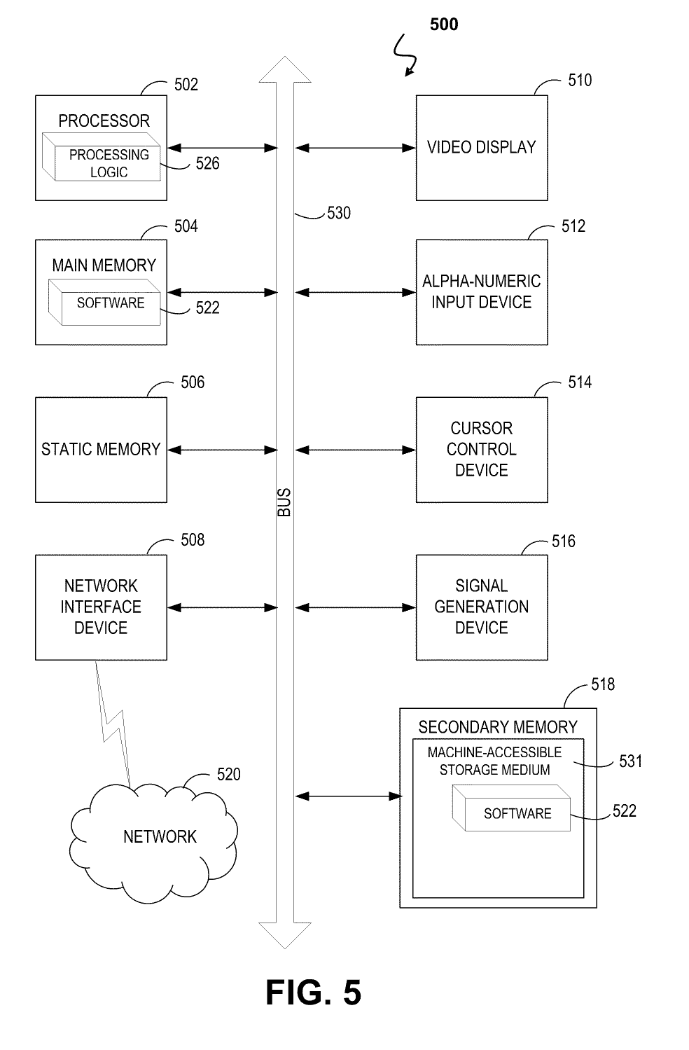

FIG. 5 illustrates a diagrammatic representation of a machine in the exemplary form of a computer system 500 which may be utilized to control one or more of the operations, process chambers or multi-chambered processing platforms described herein. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the process operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methods or functions described herein. The software 522 may also reside, completely or at least partially, within the main memory 504 and/or within the processor 502 during execution thereof by the computer system 500, the main memory 504 and the processor 502 also constituting machine-readable storage media.

The machine-accessible storage medium 531 may further be used to store a set of instructions for execution by a processing system and that cause the system to perform any one or more of the embodiments of the present invention. Embodiments of the present invention may further be provided as a computer program product, or software, that may include a machine-readable storage medium having stored thereon instructions, which may be used to program a computer system (or other electronic devices) to perform a process according to the present invention. A machine-readable storage medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, and other such non-transitory storage media known in the art.

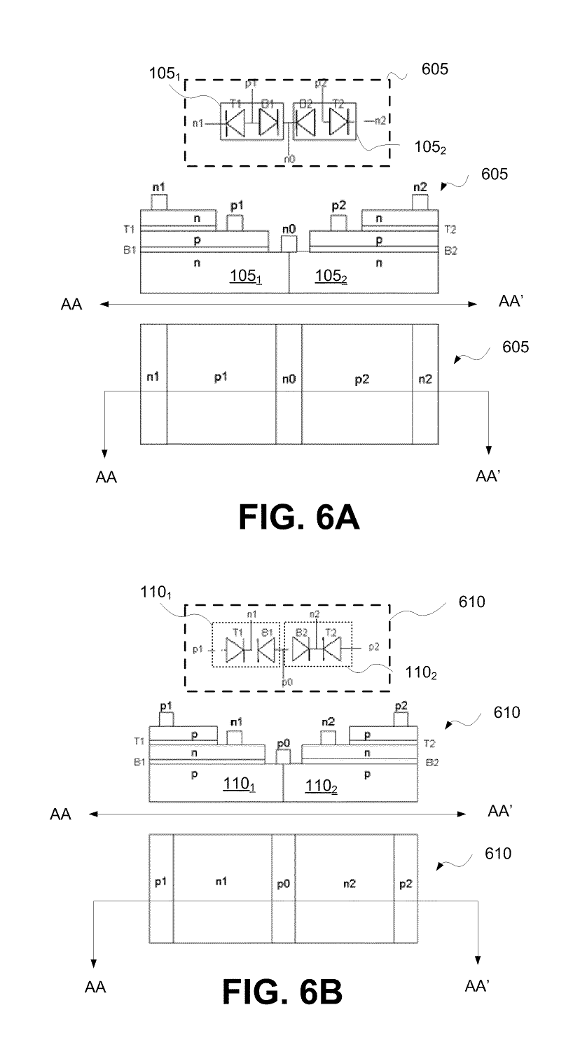

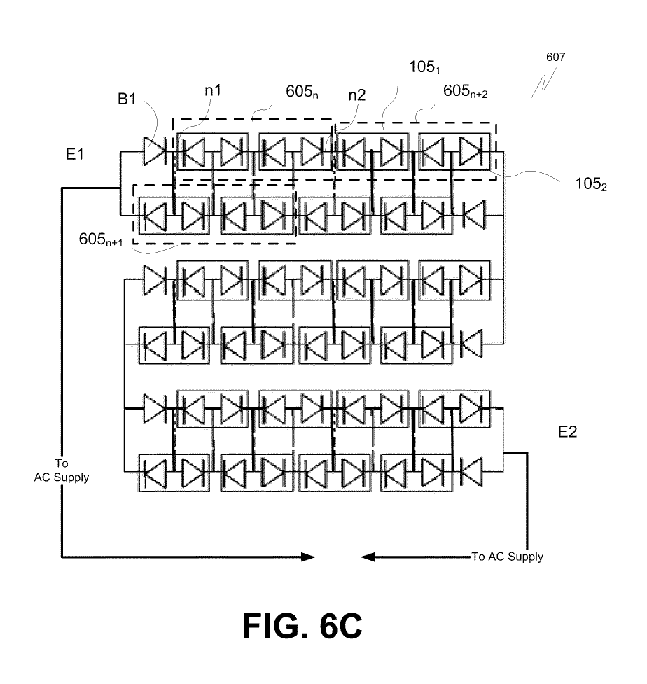

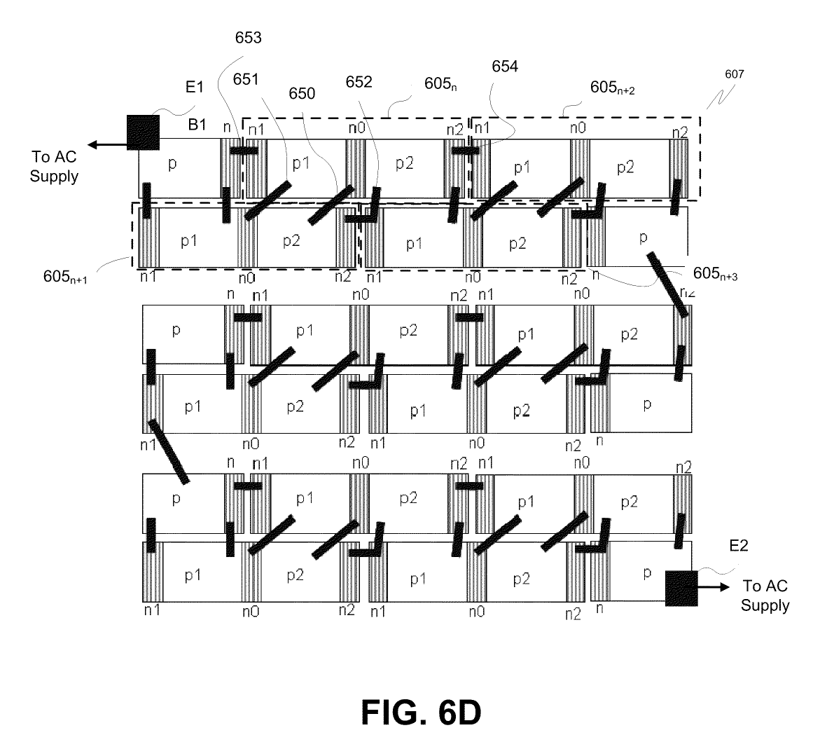

In embodiments, stacked LED structures are coupled together to from LED arrays. FIGS. 6A, 6B, 7A, 7B, 8A, 8B, 9A, 9B, 10A, and 10B illustrate multi-LED units including a plurality of stacked LED structures from which LED arrays having a very compact layout, simplified fabrication, and high performance may be provided. In the exemplary embodiments the multi-LED units include pairs of stacked LED structures which share a common terminal. FIGS. 6C, 7C, 9C and 10C illustrate exemplary LED circuits made up of arrays of multi-LED units while FIGS. 6D, 9D and 10D illustrate exemplary LED array layouts.

FIG. 6A illustrates three views of a first multi-LED unit 605 employing a plurality of anti-series npn devices formed in the GaN-based LED film stack depicted in FIG. 1C, in accordance with an embodiment of the present invention. As shown schematically, the npn anti-series multi-LED unit 605 includes both a first tandem LED structure 105₁ and a second tandem LED structure 105₂ which share an electrode n0 to form a multi-LED pair. As shown in the cross-sectional view along AA-AA,′ the first and second tandem LED structures 105₁, 105₂ are disposed adjacent to each other on a substrate (not depicted) with the contact n0 coupled to both tandem LED structures 105₁, 105₂.

In the exemplary configuration depicted, the npn anti-series multi-LED unit 605 has the common contact disposed between the two tandem LED structures 105₁, 105₂ so that the two npn anti-series structures form a four diode unit having five terminals, n0, n1, n2, p1, and p2 external to the multi-LED structure 605. In alternative embodiments, the n0 contact metallization may be separate between the two tandem LED structures 105₁, 105₂ with a higher level metal interconnect electrically coupling the n0 contacts of each tandem LED structure 105₁, 105₂ to a common potential. Thus, in reference to the method 101, either contact or interconnect metallization formed in operation 199 may couple the n0 node of each tandem LED structure 105₁, 105₂ to a common potential. As depicted in FIG. 6A, no isolation is present between the two tandem LED structures 105₁, 105₂ which improves LED packing density. While the npn anti-series multi-LED unit 605 includes four diodes (T1, B1 in the tandem LED structure 105₁ and T2, B2 in the tandem LED structure 105₂), the surface area occupied by npn anti-series multi-LED unit 605, as depicted in the plan view, is equivalent to the area of two conventional LEDs. As such, high-density monolithic integration of a LED chip can be accomplished with the tandem stacks provided with the multi-chamber growths described herein.

FIG. 6B illustrates three views of a pnp anti-series multi-LED unit 610 employing a plurality of devices formed in the GaN-based LED film stack depicted in FIG. 1E, in accordance with an embodiment of the present invention. As shown schematically, the pnp anti-series multi-LED unit 610 includes both a first tandem LED structure 110₁ and a second tandem LED structure 110₂ which share an electrode p0. As shown in the cross-sectional view along AA-AA,′ the first and second tandem LED structures 110₁, 110₂ are disposed adjacent to each other on a substrate (not depicted) with the contact p0 coupled to both tandem LED structures 110₁, 110₂. In the exemplary configuration, the pnp anti-series multi-LED unit 610 has the common contact disposed between the two tandem LED structures 110₁, 110₂ so that the two pnp anti-series structures form a four diode unit having five terminals p0, p1, p2, n1, and n2. In alternative embodiments, the p0 contact metallization may be separate between the two tandem LED structures 110₁, 110₂ with a higher level metal interconnect electrically coupling the n0 contacts of each tandem LED structure 110₁, 110₂ to a common potential. Thus, in reference to the method 102, either the contact or interconnect metallization formed in operation 199 may couple the p0 node of each tandem LED structure 110₁, 110₂ to a common potential. As depicted in FIG. 6B, no isolation is present between the two tandem LED structures 110₁, 110₂. While the pnp anti-series multi-LED unit 610 includes four diodes (T1, B1 in the tandem LED structure 110₁ and T2, B2 in the tandem LED structure 110₂), the surface area occupied by the pnp anti-series multi-LED unit 610, as depicted in the plan view, is equivalent to the area of two conventional LEDs.

FIG. 6C illustrates a schematic of an AC driven circuit 607, in accordance with an embodiment of the present invention. The AC driven circuit 607 includes a plurality of the pnp anti-series multi-LED units 605 or a plurality of the pnp anti-series multi-LED units 610 depicted in FIG. 6A or 6B, respectively, coupled together to provide a first electrode E1 and second electrode E2 to receive power from an AC power supply. In an embodiment, the AC driven circuit 607 is operable at a high voltage (e.g., 110V or 220V) and no AC/DC converter is utilized. In one embodiment, the AC driven circuit 607, includes a first multi-LED unit 605ₙ coupled with a second multi-LED unit 605ₙ₊₁ and with a third multi-LED unit 605 ₙ₊₂ to form a laddered series circuit path in which at least one series circuit path between the two electrodes E1 and E2 is forward biased by the applied AC supply at any given time.

Depending on the number of LEDs included in a given AC driven circuit, one or more diodes of a multi-LED unit may be excluded. For example, single a tandem LED structure 105₁ and a top diode B1 of a tandem stack 105 are included in the AC driven circuit 606. Hence, the AC driven circuit 607 is not limited to LEDs populations which are multiple of the number of diodes in the multi-LED unit. The AC driven circuit 607 is particularly advantageous for embodiments where the bottom diodes (B1, B2) and top diodes (T1, T2) have the same emission peaks for reduced blinking effect since there is at least on LED on at all times for a given chip area. The AC driven circuit 607 may also be advantageous for embodiments where the bottom and top diodes have different emission peaks (dichromatic). For example, in one embodiment a coating having different types of phosphors may be disposed over the tandem LED structures and the color (e.g., either warm white or cold white) can be alternated during the alternating current cycles. In other embodiments where no phosphor coating is applied, the LEDs can be alternated between two different colors at the AC supply modulation rate which may be fixed (e.g., 60 Hz) or variable to facilitate optical signal transmission, etc.

FIG. 6D illustrates a layout view of the AC driven circuit 607 depicted in FIG. 6C, in accordance with an embodiment of the present invention. Where pnp anti-series multi-LED units 605 are employed in the AC driven circuit 607, the common n0 node of the pnp anti-series multi-LED units 605ₙ is coupled with metallization 650 to p2 of the of the pnp anti-series multi-LED unit 605ₙ₊₁. The p1 node of the pnp anti-series multi-LED unit 605ₙ is coupled with metallization 651 to the common n0 node of the pnp anti-series multi-LED unit 605ₙ₊₁. The p2 node of the pnp anti-series multi-LED unit 605ₙ is coupled with metallization 652 to the n2 node of the pnp anti-series multi-LED unit 605ₙ₊₁ via the n1 node of an adjacent pnp anti-series multi-LED unit 605ₙ₊₃. The n1 node of the pnp anti-series multi-LED unit 605ₙ is coupled by metallization 653 to the n node of the diode B1 and the n2 node of the pnp anti-series multi-LED unit 605ₙ is coupled by metallization 654 to the n1 node of the pnp anti-series multi-LED unit 605ₙ₊₁. Analogous connections may be made for embodiments employing a plurality of the pnp anti-series multi-LED units 610ₙ to form the AC driven circuit 607.

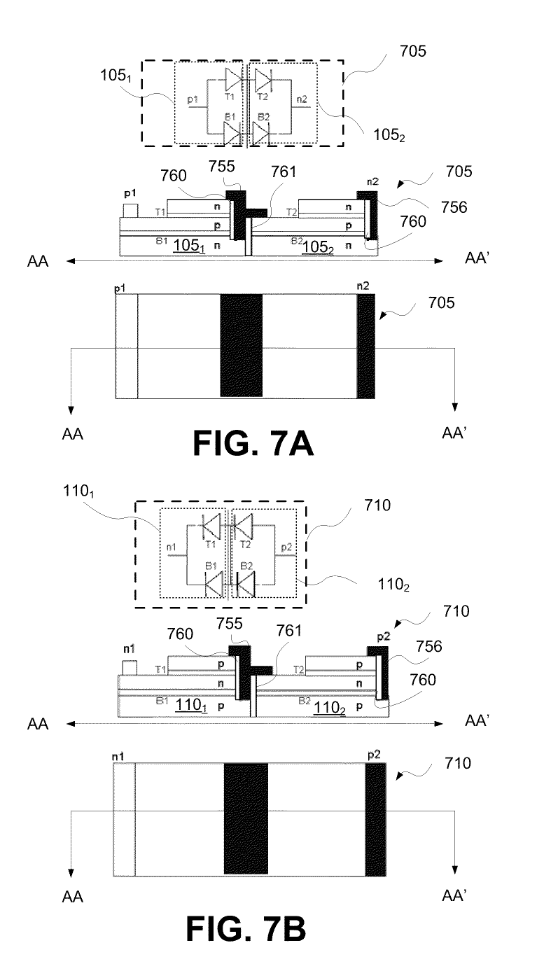

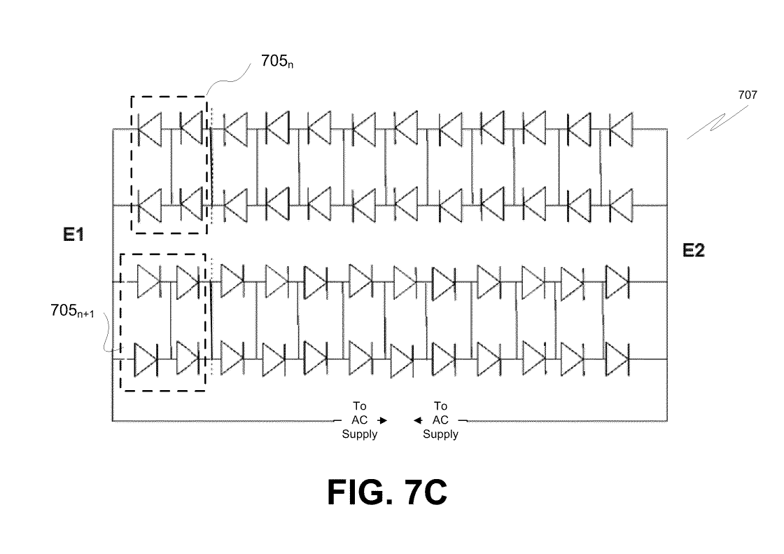

FIG. 7A illustrates three views of a second multi-LED unit 705 employing a plurality of npn devices formed in the GaN-based LED film stack depicted in FIG. 1C, in accordance with an embodiment of the present invention. As shown schematically, the npn multi-LED unit 705 includes both a first tandem LED structure 105₁ and a second tandem LED structure 105₂. As shown in the cross-sectional view along AA-AA,′ the first and second tandem LED structures 105₁, 105₂ are disposed adjacent to each other on a substrate (not depicted) with side contact metallization 751 coupling together nodes of both tandem LED structures 105₁, 105₂ to form a four diode unit having two terminals, p1 and n2 external to the multi-LED unit 705. The side contact metallization 751 electrically couples together two layers in one tandem LED stack having a same doping type to a layer in another tandem LED stack having a different doping type so that the top diode T1 is operable in parallel with the bottom diode B1 and that the top diode T2 is operable in parallel with the bottom diode B2 with the two parallel diode pairs B1/T1 and B2/T2 coupled in series. For example, in FIG. 7A, side contact sc metallization 751 extends into a trench formed in the tandem LED structure 105₁ to couple the top and bottom n-type layers together to a common potential with a sidewall dielectric (i.e. spacer) 760 insulating the side contact metallization 751 from the p-type layer. The side contact metallization 751 further extends over an isolation 761 separating the adjacent first and second tandem LED structures 105₁, 105₂ to make contact with the p-type layer in the tandem LED structure 105₂. A similar side contact metallization 756 may also be utilized for the node n2, as depicted in FIG. 7A.

For the embodiment illustrated in FIG. 1D, the side contact metallization 755 formed in operation 199 concurrent with the other contact metallization, p1 and n2. While the multi-LED unit 705 includes four diodes (T1, B1 in the tandem LED structure 105₁ and T2, B2 in the tandem LED structure 105₂), the surface area occupied by the multi-LED unit 705, as depicted in the plan view, is equivalent to the area of two conventional LEDs with a high fill factor achieved in part by the side contact metallization 751 coupling together certain terminals of the four LEDs with local interconnect so that only two contacts (p1 and n2) are external to the multi-LED unit 705. As such, high-density monolithic integration of a LED chip can be accomplished with the tandem stacks provided with the multi-chamber growths described herein.

FIG. 7B similarly illustrates three views of a second multi-LED unit 710 employing a plurality of pnp devices formed in the GaN-based LED film stack depicted in FIG. 1E, in accordance with an embodiment of the present invention. As shown schematically, the pnp multi-LED unit 710 includes both a first tandem LED structure 110₁ and a second tandem LED structure 110₂. Along AA-AA,′ the first and second tandem LED structures 110₁, 110₂ are disposed adjacent to each other on a substrate (not depicted) with side contact metallization 755 coupling together nodes of both tandem LED structures 110₁, 110₂ to form a four diode unit having two terminals, p2 and n1 external to the pnp multi-LED unit 710. The side contact metallization 755 electrically couples together two layers in one tandem LED stack having a same doping type to a layer in another tandem LED stack having a different doping type so that the top diode T1 is operable in parallel with the bottom diode B1 and that the top diode T2 is operable in parallel with the bottom diode B2 with the two parallel diode pairs B1/T1 and B2/T2 coupled in series. For the pnp multi-LED unit 710, side contact metallization 755 extends into a trench formed in the tandem LED structure 105₁ to couple the top and bottom p-type layers together to a common potential with a sidewall dielectric (i.e. spacer) 760 insulating the side contact metallization 755 from the intervening n-type layer. The side contact metallization 755 further extends over isolation 761 separating the adjacent first and second tandem LED structures 110₁, 110₂ to make contact with the n-type layer in the tandem LED structure 110₂. A similar side contact structure may also be utilized for the node n1, depicted as metallization 756 in FIG. 7B. In this embodiment also, a high fill factor achieved in part by the side contact metallization 751 coupling together certain terminals of the four LEDs with local interconnect so that only two external contacts (n1 and p2) are needed. As such, high-density monolithic integration of a LED chip can be accomplished with the tandem stacks provided with the multi-chamber growths described herein.

FIG. 7C illustrates a schematic of an AC driven circuit 707, in accordance with an embodiment of the present invention. The AC driven circuit 707 includes either a plurality of the npn multi-LED units 705 or a plurality of the pnp multi-LED units 710 depicted in FIG. 7A or 7B, respectively, coupled together to provide a first electrode E1 and second electrode E2 to receive power from an AC power supply. In an embodiment, the AC driven circuit 707 is operative at a high voltage (e.g., 110V or 220V) and no AC/DC converter is utilized. In one embodiment, the AC driven circuit 707, includes a first multi-LED unit 705ₙ coupled in parallel with a second multi-LED unit 705ₙ₊₁ across the electrodes E1 and E2 to form two parallel diode circuit branches in which each parallel diode circuit branches is alternately forward biased by the applied AC supply. The AC driven circuit 707 is particularly advantageous in embodiments where the bottom and top diodes have different emission peaks (e.g., one in blue and another in near UV) for improved color mixing or rendering and/or improved activation of phosphor for LED to white light conversion.

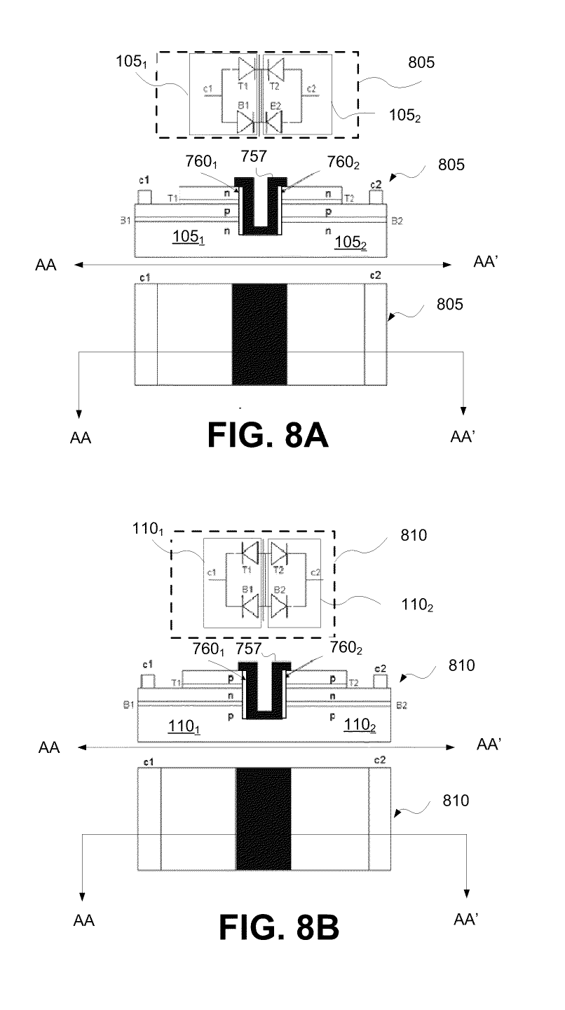

FIGS. 8A and 8B each illustrate three views third multi-LED units employing a plurality of npn and pnp devices formed in the GaN-based LED film stack depicted in FIG. 1C and FIG. 1E, respectively, in accordance with embodiments of the present invention. As shown schematically in FIG. 8A, the npn multi-LED unit 805 includes both a first tandem LED structure 105₁ and a second tandem LED structure 105₂. As shown schematically in FIG. 8B, the pnp multi-LED unit 810 includes both a first tandem LED structure 110₁ and a second tandem LED structure 110₂.

Referring to FIG. 8A, the first and second tandem LED structures 105₁, 105₂ are disposed adjacent to each other on a substrate (not depicted) with no intervening isolation and with side contact metallization 757 coupling together nodes of both tandem LED structures 105₁, 105₂ to form a four diode unit having two terminals, c1 and c2 external to the npn multi-LED unit 805. The side contact metallization 757 electrically couples together two layers in one tandem LED stack having a same doping type to two layers in the adjacent tandem LED stack having a same doping type so that the top diode T1 is operable in parallel with the bottom diode B1 and that the top diode T2 is operable in parallel with the bottom diode B2 with the two parallel diode pairs B1/T1 and B2/T2 coupled in anti-series. For example, in FIG. 7A, side contact metallization 757 extends into a trench formed in both the tandem LED structures 105₁ 105₂ to couple both the top and bottom n-type layers together to a common potential with sidewall dielectric layers (i.e. spacers) 760₁ and 760₂ insulating the side contact metallization 757 from the intervening p-type layers. In FIG. 7B, side contact metallization 757 extends into a trench formed in both the tandem LED structures 110₁ 110₂ to couple both the top and bottom n-type layers together to a common potential with sidewall dielectric layers (i.e. spacers) 760₁ and 760₂ insulating the side contact metallization 757 from the intervening n-type layers.

For the embodiment illustrated in FIG. 1D, the side contact metallization 757 is formed in operation 199 concurrent with the other contact metallization, c1 and c2. While the multi-LED units 805 and 810 including four diodes (e.g., T1, B1 in the tandem LED structure 105₁ and T2, B2 in the tandem LED structure 105₂), the surface area occupied by the multi-LED units 805 and 810, as depicted in the plan views of FIGS. 7A and 7B, respectively, is equivalent to the area of two conventional LEDs. A high fill factor is achieved in part by the side contact metallization 757 coupling together certain terminals of the four LEDs. As such, high-density monolithic integration of a LED chip can be accomplished with the tandem stacks provided with the multi-chamber growths described herein.

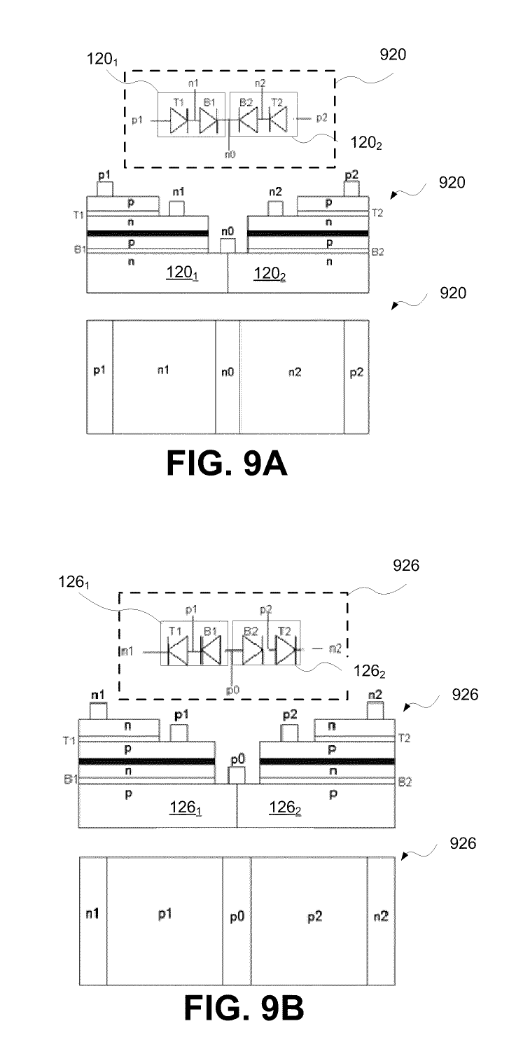

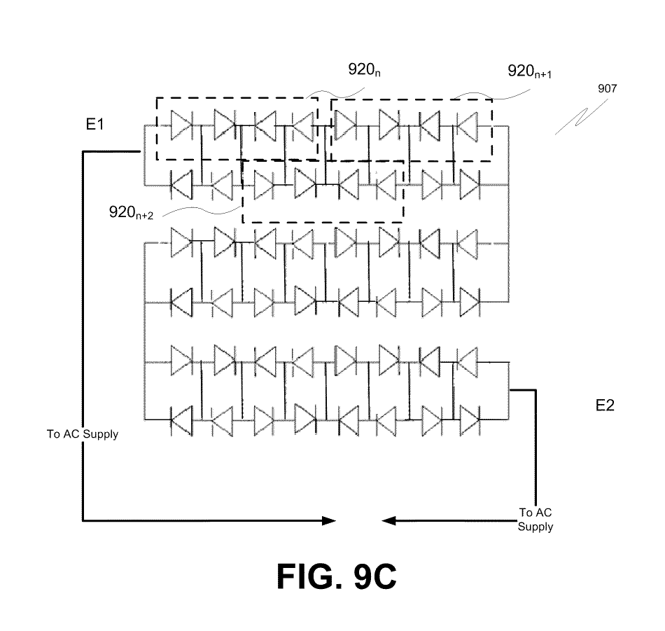

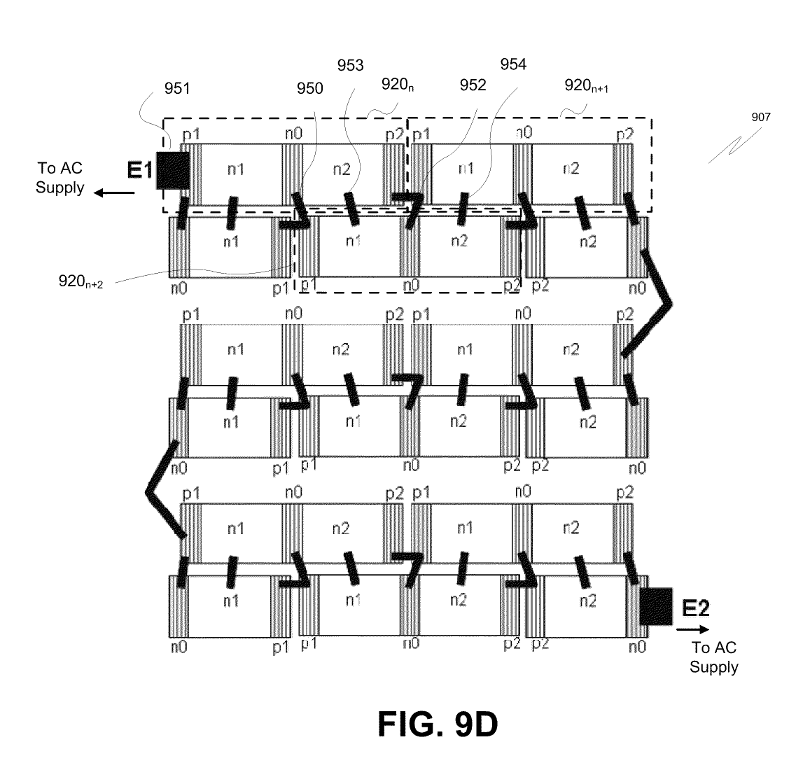

FIGS. 9A and 9B illustrate first multi-LED units employing a plurality of devices formed in the GaN-based LED film stack depicted in FIG. 1G and FIG. 1L, respectively, in accordance with embodiments of the present invention. FIG. 9A illustrates three views of a multi-LED unit 920 employing a plurality of common n-type pnpn series devices formed in the GaN-based LED film stack depicted in FIG. 1G. As shown schematically, the common n-type pnpn series multi-LED unit 920 includes both a first tandem LED structure 120₁ and a second tandem LED structure 120₂ which share an electrode n-type electrode n0. As shown in the cross-sectional view along AA-AA,′ the first and second tandem LED structures 120₁, 120₂ are disposed adjacent to each other on a substrate (not depicted) with the n-type contact n0 coupled to both tandem LED structures 120₁, 120₂ so that the two pnpn series structures form a four diode unit having five independent external terminals, n0, n1, n2, p1, and p2 external to the common n-type pnpn series multi-LED unit 920. In alternative embodiments, the n0 contact metallization may be separate between the two tandem LED structures 120₁, 120₂ with a higher level metal interconnect electrically coupling the n0 contacts of each tandem LED structure 120₁, 120₂ to a common potential. Thus, in reference to the method 101, either the contacts or interconnects formed in operation 199 may couple the n0 node of each tandem LED structure 120₁, 120₂ to a common potential. As depicted in FIG. 9A, no isolation is present between the two tandem LED structures 120₁, 120₂. While the common n-type pnpn series multi-LED unit 920 includes four diodes (T1, B1 in the tandem LED structure 120₁ and T2, B2 in the tandem LED structure 120₂), the surface area occupied by the common n-type pnpn anti-series multi-LED unit 920, as depicted in the plan view, is equivalent to the area of two conventional LEDs. As such, high-density monolithic integration of a LED chip can be accomplished with the tandem stacks provided with the multi-chamber growths described herein.

FIG. 9B illustrates three views of a common p-type npnp series multi-LED unit 926 employing a plurality of devices formed in the GaN-based LED film stack depicted in FIG. 1L, in accordance with an embodiment of the present invention. As shown schematically, the common p-type npnp anti-series multi-LED unit 926 includes both a first tandem LED stack 126₁ and a second tandem LED stack 126₂ which share an p-type electrode p0. As shown in the cross-sectional view along AA-AA,′ the first and second tandem LED structures 126₁, 126₂ are disposed adjacent to each other on a substrate (not depicted) with the contact p0 coupled to both tandem LED structures 126₁, 126₂ so that the two pnpn series structures form a four diode unit having five terminals, p0, p1, p2, n1, and n2. In alternative embodiments, the p0 contact metallization may be separate between the two tandem LED structures 126₁, 126₂ with a higher level metal interconnect electrically coupling the n0 contacts of each tandem LED stack 126₁, 126₂ to a common potential. Thus, in reference to the method 102, either the contacts or interconnects formed in operation 199 may couple the p0 node of each tandem LED stack 126₁, 126₂ to a common potential. As depicted in FIG. 9B, no isolation is present between the two tandem LED structures 126₁, 126₂. While the common p-type npnp series multi-LED unit 926 includes four diodes (T1, B1 in the tandem LED stack 126₁ and T2, B2 in the tandem LED stack 126₂), the surface area occupied by the common p-type npnp anti-series multi-LED unit 926, as depicted in the plan view, is equivalent to the area of two conventional LEDs.

FIG. 9C illustrates a schematic of an AC driven circuit 907, in accordance with an embodiment of the present invention. The AC driven circuit 907 includes a plurality of the common n-type pnpn series multi-LED units 920 or a plurality of the common p-type pnpn series multi-LED units 926 depicted in FIG. 9A or 9B, respectively, coupled together to provide a first electrode E1 and second electrode E2 to receive power from an AC power supply. In an embodiment, the AC driven circuit 907 is operative at a high voltage (e.g., 110V or 220V) and no AC/DC converter is utilized. In one embodiment, the AC driven circuit 907, includes a first multi-LED unit 920ₙ coupled with a second multi-LED unit 920ₙ₊₁ and with a third multi-LED unit 920ₙ₊₂ to form a laddered series circuit path in which at least one series circuit path between the two electrodes E1 and E2 is forward biased by the applied AC supply at any given time.

Like the AC driven circuit 607, the AC driven circuit 907 is particularly advantageous where the bottom diodes (B1, B2) and top diodes (T1, T2) have the same emission peaks for reduced blinking effect since there is at least on LED on at all times for a given chip area. The AC driven circuit 907 may also be advantageous where the bottom and top diodes have different emission peaks. For example, in one embodiment a coating having different types of phosphors may be disposed over the tandem LED structures and the color (e.g., either warm white or cold white) can be alternated during the alternating current cycles. In other embodiments where no phosphor coating is applied, the LEDs can be alternated between two different colors at the power supply modulation rate which may be fixed (e.g., 60 Hz) or variable to facilitate wideband optical signal transmission, etc.

FIG. 9D illustrates a layout view of the AC driven circuit 907 depicted in FIG. 9C, in accordance with an embodiment of the present invention. Where common n-type pnpn series multi-LED units 920 are employed in the AC driven circuit 907, the common n0 node of the pnpn series multi-LED units 920ₙ is coupled with metallization 950 to p1 of the of the pnpn series multi-LED unit 920ₙ₊₂. The p1 node of the pnpn series multi-LED unit 920ₙ is coupled with metallization 951 to the electrode E1. The p2 node of the pnpn series multi-LED unit 920ₙ is coupled with metallization 952 to the n0 node of the pnpn series multi-LED unit 920ₙ₊₂ and the p1 node of an adjacent pnpn series multi-LED unit 920ₙ₊₁. The n1 node of the pnpn series multi-LED unit 620ₙ₊₂ is coupled by metallization 953 to the n2 node of the pnpn series multi-LED unit 920ₙ and the n2 node of the pnpn series multi-LED unit 920ₙ₊₂ is coupled by metallization 954 to the n1 node of the pnpn series multi-LED unit 920ₙ₊₁. Analogous connections may be made for embodiments employing a plurality of the common p-type npnp series multi-LED units 926 to form the AC driven circuit 907.

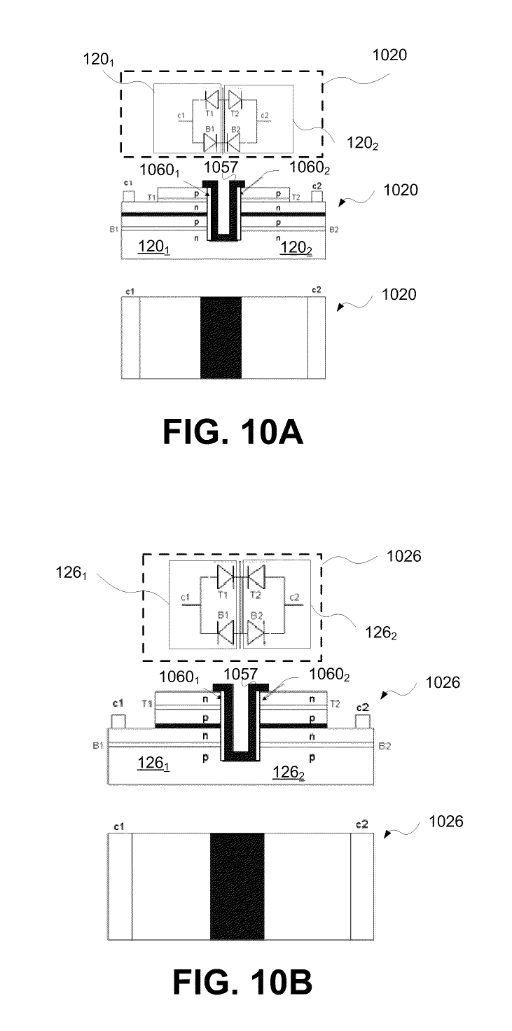

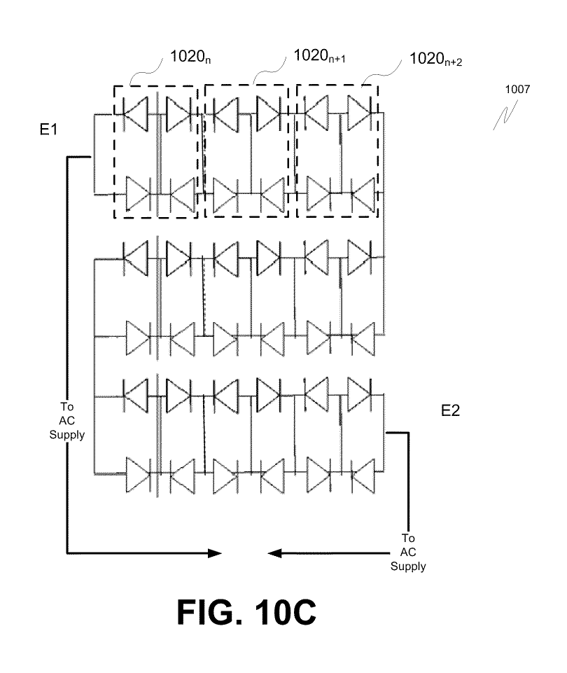

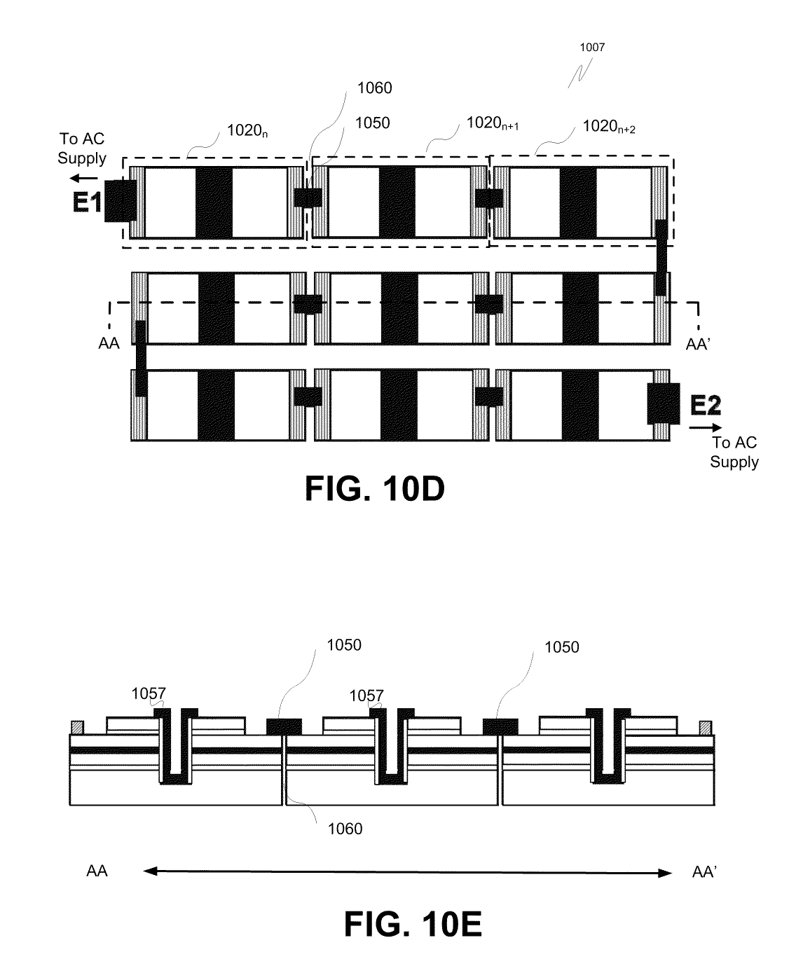

FIGS. 10A and 10B illustrate second multi-LED units 1020 and 1026 employing a plurality of devices formed in the GaN-based LED film stack depicted in FIG. 1G and FIG. 1N, respectively, in accordance with embodiments of the present invention. FIGS. 10A and 10B each illustrate three views of a pnpn multi-LED unit 1020 employing a plurality of pnpn devices and a npnp multi-LED unit 1026 employing a plurality of npnp devices, respectively. As shown schematically in FIG. 10A, the pnpn multi-LED unit 1020 includes both a first tandem LED structure 120₁ and a second tandem LED structure 1020₂. As shown schematically in FIG. 10B, the npnp multi-LED unit 1026 includes both a first tandem LED stack 126₁ and a second tandem LED stack 126₂.

Referring to FIG. 10A, the first and second tandem LED structures 120₁, 120₂ are disposed adjacent to each other on a substrate (not depicted) with no intervening isolation. Side contact metallization 1057 couples together nodes of both tandem LED structures 120₁, 120₂ to form a four diode unit including a pair of tandem LEDs with two terminals, c1 and c2 external to the pnpn multi-LED unit 1020. The side contact metallization 1057 electrically couples together two layers in one tandem LED stack having a complementary doping type to two layers in the adjacent tandem LED stack having a complementary doping type so that the top diode T1 is operable in anti-series with the bottom diode B1 and that the top diode T2 is operable in anti-series with the bottom diode B2 with the two diode pairs B1/T1 and B2/T2 further coupled in anti-series. For example, in FIG. 10A, side contact metallization 1057 extends into a trench formed in both the tandem LED structures 120₁, 120₂ to couple both the top p-type layer and bottom n-type layer together to a common potential with sidewall dielectric layers (i.e. spacers) 1060₁ and 1060₂ insulating the side contact metallization 1057 from the intervening n-type, p-type layers, and tunnel junction. Similarly, in FIG. 10B, side contact metallization 1057 extends into a trench formed in both the tandem LED structures 126₁ 126₂ to couple both the top n-type and bottom p-type layers together to a common potential with sidewall dielectric layers (i.e. spacers) 1060₁ and 1060₂ insulating the side contact metallization 1057 from the intervening n-type, p-type layers, and tunnel junction.

In other embodiments, the side contact metallization 1057 is applied to the top n current spreading layer structures 129 (FIG. 1B and FIG. 1K). For such embodiments, side contact metallization 1057 couples together nodes of two adjacent tandem LED structures 129 to form a four diode unit including a pair of tandem LEDs with two terminals, c1 and c2 external to the n-contacted pnpn multi-LED unit substantially as depicted for the pnpn multi-LED unit 1020 (FIG. 10A). In other embodiments, the side contact metallization 1057 is applied to the bottom n current spreading layer structures 130 (FIG. 1B and FIG. 1Q). For such embodiments, side contact metallization 1057 couples together nodes of two adjacent tandem LED structures 130 to form a four diode unit including a pair of tandem LEDs with two terminals, c1 and c2 external to the n-contacted npnp multi-LED unit substantially as depicted for the npnp multi-LED unit 1026 (FIG. 10B).

For the embodiment illustrated in FIG. 1D, the side contact metallization 1057 is formed in operation 199 concurrent with the other contact metallization, c1 and c2. While the multi-LED units 1020 and 1026 include four diodes (e.g., T1, B1 in the tandem LED structure 105₁ and T2, B2 in the tandem LED structure 105₂), the surface area occupied by the multi-LED units 1020 and 1026, as depicted in the plan views of FIGS. 9A and 9B, respectively, is equivalent to the area of two conventional LEDs. A high fill factor is achieved in part by the side contact metallization 1057 coupling together certain terminals of the four LEDs. As such, high-density monolithic integration of a LED chip can be accomplished with the tandem stacks provided with the multi-chamber growths described herein.

FIG. 10D illustrates a schematic of an array of the multi-LED pairs depicted in FIG. 10A or 10B forming an AC driven circuit 1070 to be coupled to an AC power source, in accordance with an embodiment of the present invention. The AC driven circuit 1007 includes a plurality of the pnpn a multi-LED units 1020 or a plurality of the npnp anti-series multi-LED units 1026 (which may further include a top or bottom n-current spreading layer), respectively, coupled together to provide a first electrode E1 and second electrode E2 to receive power from an AC power supply. In an embodiment, the AC driven circuit 1007 is operative at a high voltage (e.g., 110V or 220V) and no AC/DC converter is utilized. In one embodiment, the AC driven circuit 1007, includes a first multi-LED unit 1020ₙ coupled in series with a second multi-LED unit 1020ₙ₊₁ which is further coupled in series with a third multi-LED unit 1020 ₙ₊₂ to form a laddered series circuit path in which at least one series circuit path between the two electrodes E1 and E2 is forward biased by the applied AC supply at any given time.

Like the AC driven circuit 607, the AC driven circuit 1007 is particularly advantageous where the bottom diodes (B1, B2) and top diodes (T1, T2) have the same emission peaks for reduced blinking effect since there is at least on LED on at all times for a given chip area. The AC driven circuit 1007 may also be advantageous where the bottom and top diodes have different emission peaks. For example, in one embodiment a coating having different types of phosphors may be disposed over the tandem LED structures and the color (e.g., either warm white or cold white) can be alternated during the alternating current cycles. In other embodiments where no phosphor coating is applied, the LEDs can be alternated between two different colors at the power supply modulation rate which may be fixed (e.g., 60 Hz) or variable to facilitate wideband optical signal transmission, etc.

FIG. 10D illustrates a layout view of the AC driven circuit 1007 depicted in FIG. 10C, in accordance with an embodiment of the present invention. FIG. 10F illustrates a cross-section of the AC driven circuit 1007 depicted in FIG. 10E. As illustrated, the contacts c1 and c2 are connected together with metallization 1050 extending over isolation 1060 to couple the first multi-LED unit 1020ₙ coupled in series with the second multi-LED unit 1020ₙ₊₁. Thus, the embodiment depicted in FIG. 10D has a particularly high fill factor as the contacts c1 and c2 external to the multi-LED unit 1020 are coupled together with one continuous metallization 1050. Analogous connections may be made for embodiments employing a plurality of the pnpn multi-LED units 1026 to form the AC driven circuit 1007 from the alternate tandem LED stack.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for growing a multi-junction LED film stack, comprising:
loading a substrate into a multi-chambered epitaxy system;
growing a pGaN layer on the substrate in the first epitaxial chamber;
transferring the substrate to a second epitaxial chamber of the multi-chambered epitaxy system; and
growing a nGaN layer over the pGaN layer in the second epitaxial chamber.

2. The method of claim 1, wherein transferring of the substrate from the first epitaxial chamber to the second epitaxial system is performed in-vacuo.

3. The method of claim 1, further comprising:
transferring the substrate to a third epitaxial chamber of the multi-chambered epitaxy system; and
growing a multiple quantum well structure prior to growing the pGaN layer and subsequent to growing the nGaN layer.

4. The method of claim 1, wherein the pGaN layer is a doped with Mg.

5. The method of claim 4, further comprising forming a tunnel junction over the pGaN layer.

6. The method of claim 1, further comprising:
transferring the substrate to the first epitaxial chamber of the multi-chambered epitaxy system; and
growing a second pGaN layer over the nGaN layer in the first epitaxial chamber.

7. A multi-junction LED, comprising:
an active region;
a p-type GaN layer adjacent to the active region; and
a first tunnel junction formed on the p-type GaN layer, wherein the first tunnel junction comprises an abrupt non-p-type material to p-type material metallurgical junction.

8. The multi-junction LED of claim 7, wherein the width of the abrupt non-p-type material to p-type material junction is less than 50 nm.

9. The multi-junction LED of claim 7, wherein the first tunnel junction comprises an interface between a highly doped n-type material and a highly doped p-type material, and wherein the interface has a thickness less than 50 nm.

10. A system for processing a substrate, the system comprising:
a first chamber to grow a p-type doped GaN epitaxial layer; and
a second chamber to grow a non-p-type doped GaN epitaxial layer, wherein the first chamber is configured to provide a magnesium (Mg) dopant during a growth of the p-type doped GaN epitaxial layer, and wherein the second chamber is substantially free of Mg.

11. The system as in claim 10, further comprising:
a transfer module coupled to each of the first and second chamber; and
a robotic handler to transfer the substrate between the first and second chambers in-vacuo; and
a controller to execute the transfer between the p-type doped GaN epitaxial layer growth and the non-p-type doped GaN epitaxial layer growth.

12. The system as in claim 11, further comprising a third epitaxial chamber configured to epitaxially grow a multiple quantum well (MQW) structure after either the p-type doped GaN epitaxial layer growth and the non-p-type doped GaN epitaxial layer growth.

13. The system as in claim 12, wherein the third chamber is substantially free of Mg.

14. A computer-readable non-transitory storage medium having stored thereon a set of instructions which when executed cause a system to perform a method of claim 1.

15. A multi-LED array disposed on a substrate, the multi-LED array comprising:
a plurality of multi-junction LED pairs spaced apart on the substrate with an isolation region disposed between each multi-junction LED pair; wherein each of the plurality of multi-junction LED pairs further comprises
a first multi-junction LED
a second multi-junction LED adjacent to the first multi-junction LED; and
a first metallization common between a node of the first multi-junction LED and a node of the second multi-junction LED; and
a second metallization connecting adjacent ones of the plurality of multi-junction LED pairs.

16. The multi-LED array as in claim 15, wherein the first and second multi-junction LEDs share in common a continuous bottom doped semiconductor layer free from intervening electrical isolation.

17. The multi-LED array as in claim 15, wherein the multi-junction LED pairs comprises at least one of: a common n-type npn anti-series unit with the continuous bottom doped semiconductor layer being n-type; a common p-type pnp anti-series unit with the continuous bottom doped semiconductor layer being p-type, a common n-type pnpn series unit with the continuous bottom doped semiconductor layer being n-type, or a common p-type npnp series unit with the continuous bottom doped semiconductor layer being p-type.

18. The multi-LED array as in claim 15, wherein each multi-junction LED pair comprises a first and second tandem stacked LED structure and wherein each of the first and second tandem stacked LED further comprises:
a first n-type layer;
a first p-type GaN layer disposed above the first n-type layer;
a second n-type layer disposed above the p-type GaN layer; and
a second p-type GaN layer disposed above the second n-type layer.

19. The multi-LED array of claim 18, wherein the first metallization couples to a same potential the first n-type layer and the second p-type GaN layer in each of the first and second tandem stacked LEDs of a first a multi-junction LED pair, and wherein the second metallization couples the second n-type layer in the first multi-junction LED pair to the second n-type layer of a second multi-junction LED pair.

20. The multi-LED array of claim 18, wherein the first metallization is electrically isolated from the second n-type layer by a sidewall spacer dielectric.
